(19) United States
(12) Patent Application Publication
(10) Pub. No.: US 2025/0215614 A1
(43) Pub. Date: Jul. 3, 2025

(54) GROUP III NITRIDE STACK AND METHOD OF MANUFACTURING GROUP III NITRIDE STACK

(71) Applicant: SUMITOMO CHEMICAL COMPANY, LIMITED, Tokyo (JP)

(72) Inventors: Taiki YAMAMOTO, Hitachi-shi (JP); Hiroyuki TOMIOKA, Hitachi-shi (JP)

(73) Assignee: SUMITOMO CHEMICAL COMPANY, LIMITED, Tokyo (JP)

(21) Appl. No.: 19/000,142

(22) Filed: Dec. 23, 2024

(30) Foreign Application Priority Data
Dec. 27, 2023 (JP) 2023-221650
Dec. 27, 2023 (JP) 2023-221651
Dec. 27, 2023 (JP) 2023-221652
Dec. 27, 2023 (JP) 2023-221653

(51) Int. Cl. C30B 29/40; C30B 25/18; C30B 29/68

(52) U.S. Cl. CPC C30B 29/40; C30B 25/186; C30B 29/68

(57) ABSTRACT

This group III nitride stack includes a SiC substrate and a stack structure provided on the SiC substrate and formed by epitaxially growing a group III nitride crystal, wherein the stack structure has an average density of surface defects of 10.0 defects/cm² or less in an internal region of a surface of the stack structure, the surface defects each having a size of 0.165 μm or more and 2.0 μm or less, the internal region being a region excluding a width of 5 mm from an outer edge of the surface of the stack structure, and when the internal region is segmented into a plurality of 10 mm-square region segments and a density of the surface defects in each region segment is measured, the maximum value of the density is 50.0 defects/cm² or less.

### FIELD AND BACKGROUND OF THE INVENTION

The present disclosure relates to a group III nitride stack and a method of manufacturing the group III nitride stack.

Group III nitride-based high electron mobility transistors (HEMTs) are widely used as power amplifiers for a base station for mobile phones (for example, Japanese Patent Laid Open Publication No. 2006-286741). With group III nitride-based HEMTs, electric power that can be supplied to a single element can be significantly increased compared to Si-based devices that have been conventionally used. Accordingly, a base station can be reduced in size and installation costs can be significantly reduced.

### SUMMARY OF THE INVENTION

Semiconductor devices such as HEMTs are fabricated from group III nitride stacks. From the viewpoint of improving device characteristics of semiconductor devices, it is required to improve the quality of a group III nitride crystal.

An objective of the present disclosure is to provide a technology for improving crystal quality in a group III nitride stack.

According to one aspect of the present disclosure, there is provided a group III nitride stack including
a SiC substrate and
a stack structure provided on the SiC substrate and formed by epitaxially growing a group III nitride crystal, wherein
the stack structure has an average density of surface defects of 10.0 defects/cm² or less in an internal region of a surface of the stack structure, the surface defects each having a size of 0.165 μm or more and 2.0 μm or less, the internal region being a region excluding a width of 5 mm from an outer edge of the surface of the stack structure, and
when the internal region is segmented into a plurality of 10 mm-square region segments and a density of the surface defects in each region segment is measured, the maximum value of the density is 50.0 defects/cm² or less.

According to another aspect of the present disclosure, there is provided a group III nitride stack including
a SiC substrate and
a stack structure provided on the SiC substrate and formed by epitaxially growing a group III nitride crystal, wherein
the stack structure has relative yellow intensities of 1.30 or less, each of the relative yellow intensities being a ratio of yellow emission intensity to band edge emission intensity of photoluminescence at a surface center of the stack structure, and
a fluctuation rate (Xₘₐₓ−Xₘᵢₙ)/X_{avg} of the relative yellow intensities is 20% or less, wherein in the fluctuation rate, Xₘₐₓ, Xₘᵢₙ, and X_{avg} respectively denote the maximum value, minimum value, and average of the relative yellow intensities taken at three or more points in an internal region of the surface of the stack structure, the internal region excluding a width of 5 mm from the outer edge of the surface, the three or more points being freely selected along a central line of the surface, the three or more points including the center of the surface and two or more points spaced apart from the center.

According to yet another aspect of the present disclosure,
there is provided a method of manufacturing a group III nitride stack, the method including
(a) preparing a SiC substrate,
(b) supplying a halogen-containing gas onto the SiC substrate to desorb Si from a principal surface of the SiC substrate and form a Si-deficient region in a surface layer of the principal surface,
(c) supplying a hydrogen-containing gas onto the SiC substrate having the Si-deficient region to remove the Si-deficient region, and performing surface treatment of the principal surface, and
(d) growing a group III nitride crystal on the principal surface having undergone the treatment.

According to the present disclosure, crystal quality can be improved in the group III nitride stack.

### BRIEF DESCRIPTION OF THE DRAWINGS

FIG. 1 is a schematic cross-sectional view illustrating a group III nitride stack according to a first embodiment of the present disclosure.

FIG. 2 is a diagram for explaining a case where a maximum value of defect density is calculated.

FIG. 3 is a flowchart illustrating a method of manufacturing the group III nitride stack according to the first embodiment of the present disclosure.

FIG. 4A is a schematic view illustrating a case where an altered layer is formed on a part of a principal surface of a SiC substrate.

FIG. 4B is a schematic view illustrating a case where the altered layer has been removed in FIG. 4A.

FIG. 5A is a schematic view illustrating a case where the altered layer is formed over the entire area of the principal surface of the SiC substrate.

FIG. 5B is a schematic view illustrating a case where the altered layer has been removed in FIG. 5A.

FIG. 6 is a schematic diagram of a photoluminescence emission spectrum obtained with a group III nitride crystal.

FIG. 7 is a schematic diagram for explaining a case where a fluctuation rate of relative yellow intensities is calculated.

FIG. 8 is a photoluminescence emission spectrum of a stack structure of Sample 1.

FIG. 9 is a photoluminescence emission spectrum of a stack structure of Sample 4.

FIG. 10A is a schematic view illustrating the process of preparing the SiC substrate 10 (stack structure 100) according to a second embodiment of the present disclosure, where a group III nitride has adhered (a layer 20 constituted from the group III nitride has been formed) on a principal surface 11 of the SiC substrate 10.

FIG. 10B is a schematic diagram illustrating the process of carrying the stack structure 100 into a treatment apparatus 200 and performing a pretreatment prior to removing the layer 20.

FIG. 11A is a schematic diagram illustrating the process of supplying a halogen-containing gas onto the SiC substrate 10 to remove the layer 20 (group III nitride) from the principal surface 11 of the SiC substrate 10.

FIG. 11B is a schematic view illustrating the process of supplying a hydrogen-containing gas onto the SiC substrate 10 from which the layer 20 (group III nitride) has been removed to modify the principal surface 11.

FIG. 12 is a timing chart of temperature and gas supply in the regeneration treatment of the SiC substrate 10.

FIG. 13 is a schematic view illustrating a susceptor 220 relating to the regeneration treatment of the SiC substrate 10 according to a modification example of the second embodiment.

FIG. 14 is a schematic view illustrating the process of growing a new layer 20a (crystal) constituted from a group III nitride on the principal surface 11 of the regenerated SiC substrate 10a (on the modified principal surface 11 of the SiC substrate 10).

FIG. 15A is a schematic view illustrating the process of preparing the substrate 10 (stack structure 100) according to a third embodiment of the present disclosure, where the layer 20 constituted from a group III nitride has been deposited on the principal surface 11 of the substrate 10.

FIG. 15B is a schematic diagram illustrating the process of carrying the stack structure 100 into the treatment apparatus 200A and performing a pretreatment prior to removing the layer 20.

FIG. 16A is a schematic diagram illustrating the process of supplying a halogen-containing gas onto the substrate 10 to remove the layer 20 (group III nitride) from the principal surface 11 of the substrate 10.

FIG. 16B is a schematic view illustrating the process of supplying a hydrogen-containing gas onto the substrate 10 from which the layer 20 (group III nitride) has been removed to modify the principal surface 11.

FIG. 17 is a graph illustrating an example of a change in reflectance of monitor light 261. FIG. 18A is a schematic diagram illustrating the susceptor 220 on which a plurality of substrates 10 are placed and a measurement position 262 of the monitor light 261 in a modification example of the third embodiment.

FIG. 18B is a schematic diagram illustrating the vicinities of the measurement position 262.

FIG. 19 is a schematic view illustrating the process of growing a new layer 20a constituted from a group III nitride on the principal surface 11 of a regenerated substrate 10a.

### DETAILED DESCRIPTION

### First Embodiment

A first embodiment of the present disclosure will be described below with reference to drawings. It should be noted that the present disclosure is not limited to the following examples, but shall be defined by the scope of the claims and is intended to encompass all modifications that are within the meaning and scope equivalent to the scope of the claims.

### (1) Group III Nitride Stack

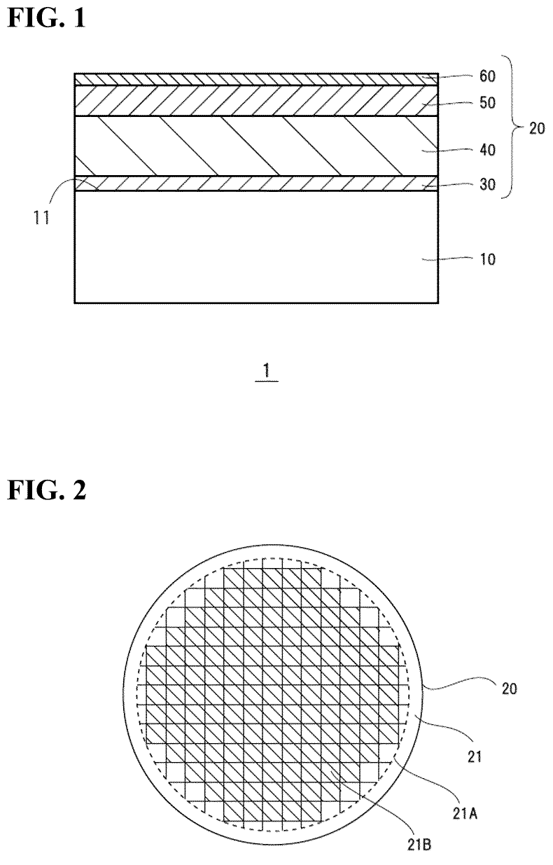

A group III nitride stack according to the present embodiment will be described with reference to FIG. 1. FIG. 1 is a schematic cross-sectional view illustrating a group III nitride stack according to the present embodiment.

Hereinafter, for a crystal such as a group III nitride semiconductor having a wurtzite structure, the <0001> axis is referred to as a “c-axis”, and the (0001) plane is referred to as a “c-plane”.

As illustrated in FIG. 1, a group III nitride stack 1 (hereinafter also referred to as “stack 1”) includes, for example, a SiC substrate 10 and a stack structure 20 formed by epitaxially growing a group III nitride crystal. The stack structure 20 is formed by growing a group III nitride crystal represented by a composition formula of InₓAl_{y}GaN (0≤x≤1, 0≤y≤1, x+y≤1). In the present embodiment, a case where the stack structure 20 includes a nucleation layer 30, a channel layer 40, and a barrier layer 50 and a cap layer 60 as functional layers will be described as an example. The functional layer is constituted from a group III nitride crystal represented by a composition formula of InₓAl_{y}Ga_{(1-x-y)}N (0≤x≤1, 0≤y≤1, x+y≤1).

### (SiC Substrate)

The SiC substrate 10 is a base substrate for epitaxially growing the stack structure 20. As will be described later, the SiC substrate 10 is configured such that surface defects therein can be reduced when surface treatment is performed on the principal surface 11 and the stack structure 20 is crystal-grown on the principal surface 11. In addition, the SiC substrate 10 is configured such that the stack structure 20 can be formed with high crystal quality and less yellow light emission as a result of surface treatment being performed on the principal surface 11. The principal surface 11 is at least partially surface-treated, and preferably, the entirety thereof is surface-treated. As SiC constituting the SiC substrate 10, for example, semi-insulating SiC of polytype 4H or polytype 6H is used. Here, the term “semi-insulating” refers to, for example, a condition in which the specific resistance is 10⁵ Ωcm or more. The surface of the SiC substrate 10 serving as a base for growing the stack structure 20 is, for example, a (0001) plane (a silicon plane of a c-plane).

The SiC substrate 10 preferably has a large area in order to improve productivity in manufacturing a semiconductor device, for example. Specifically, the diameter of the SiC substrate 10 is, for example, 2 inches (50 mm) or more, preferably 4 inches (100 mm) or more, and more preferably 6 inches (150 mm) or more.

The thickness of the SiC substrate 10 is not particularly limited and depends on the diameter of the SiC substrate 10. Specifically, the thickness of the SiC substrate 10 having a diameter of 2 inches is, for example, 300 μm or more and 500 μm or less (typically 430 μm), the thickness of the SiC substrate 10 having a diameter of 4 inches is, for example, 400 μm or more and 1000 μm or less (typically 500 μm), and the thickness of the SiC substrate 10 having a diameter of 6 inches is, for example, 400 μm or more and 1500 μm or less (typically 500 μm).

### (Nucleation Layer)

The nucleation layer 30 is provided on the SiC substrate 10. The nucleation layer 30 functions as a nucleation layer that generates crystal nuclei for growing a channel layer 40 described later. The nucleation layer 30 is formed by epitaxially growing a group III nitride crystal on the surface-treated principal surface 11 of the SiC substrate 10. For example, the nucleation layer 30 is constituted from AlN. The thickness of the nucleation layer 30 is not particularly limited, but is preferably 1 nm or more and 100 nm or less, for example.

### (Channel Layer)

The channel layer 40 is provided on the nucleation layer 30. The channel layer 40 functions as a channel layer through which electrons travel during operation of a semiconductor device such as an HEMT. The channel layer 40 is formed, for example, by epitaxially growing a group III nitride crystal on the principal surface of the nucleation layer 30. The channel layer 40 is constituted from a group III nitride represented by a composition formula of InₓAl_{y}Ga_{(1-x-y)}N (0≤x≤1, 0≤y≤1, x+y≤1), and is constituted from GaN, for example. The low-index crystal plane closest to the principal surface of the channel layer 40 is, for example, a c-plane ((0001) plane, Ga plane). The thickness of the channel layer 40 is not particularly limited, but is preferably, for example, 3 nm or more and less than 1 μm. The thickness of the channel layer 40 can be appropriately changed in accordance with the characteristics required for the semiconductor device, and may be thick in the case of reducing a leakage current or may be thin in the case of improving an RF response speed, for example. The channel layer 40 may be provided directly on the nucleation layer 30, or may be provided on the nucleation layer 30 via a known buffer layer provided on the nucleation layer 30, for example.

### (Barrier Layer)

The barrier layer 50 is provided on the channel layer 40. The barrier layer 50 generates a two-dimensional electron gas (2DEG) in the channel layer 40 and functions as a barrier layer that spatially confines the 2DEG in the channel layer 40. The barrier layer 50 is formed by, for example, heteroepitaxially growing a group III nitride crystal on the principal surface of the channel layer 40. For example, the barrier layer 50 is constituted from a group III nitride having an electron affinity smaller than that of a group III nitride crystal constituting the channel layer 40, for example, AlGaN containing aluminum (Al) and gallium (Ga). The thickness of the barrier layer 50 is preferably 1 nm or more and 80 nm or less, for example.

### (Cap Layer)

The cap layer 60 is provided on the barrier layer 50. The cap layer 60 is interposed between the barrier layer 50 and an electrode provided thereon in order to improve device characteristics (e.g., controllability of threshold voltage) of a semiconductor device such as an HEMT. The cap layer 60 is formed according to need, but may be omitted, as appropriate.

### (Surface Defects)

In the stack 1 of the present embodiment, the stack structure 20 is formed by epitaxial growth on the surface-treated principal surface 11 of the SiC substrate 10. Therefore, the stack structure 20 is configured so that the occurrence of surface defects can be suppressed and the density of the surface defects can be reduced.

Surface defects in the stack structure 20 will now be described.

A surface defect is caused by a combination of different factors such as the surface state and crystallinity of the base substrate. For example, at the time of crystal growth, a surface defect may in some cases occur on the surface of a region where dislocations with large distortion or locally dense dislocations are present. In addition, for example, a surface defect may in some cases occur on the crystal surface due to the surface state of the base, such as foreign matter having adhered to the base surface or surface roughness. In addition, for example, when impurities are mixed into the crystal during the growth, a surface defect may occur on the crystal surface. Further, for example, although various polytypes exist in the SiC substrate 10, the polytypes on the surface may not be uniform, and an abnormality may occur in crystal growth due to a difference in polytypes, leading to a possible surface defect. Specifically, various polytypes such as 3C, 4H, and 6H exist in the SiC substrate 10. However, for example, even in the case of a 6H polytype substrate, polytypes other than 6H may be present on the surface thereof. This difference in polytype is assumed as being a cause of surface defects during crystal growth.

The surface defects are fine irregularities (growth pits) that appear on the surface of the stack structure 20 due a combination of factors as has been described. The presence of the surface defect can be confirmed and detected from the manner of reflection or scattering of the irradiation light when the surface of the stack structure 20 is irradiated with laser light and scanned. In the present embodiment, the surface defects each have a size of 0.165 μm or more and 2.0 μm or less when seen in a plan view, and mean defects that are generated by crystal growth, and substantially do not include foreign matter and the like (for example, external particles) having adhered to the crystal surface. The surface of the stack structure 20 refers to the surface of the uppermost layer of the stack structure 20. In the present embodiment, since the uppermost layer of the stack structure 20 is the cap layer 60, the surface of the stack structure 20 is the surface of the cap layer 60.

In the present embodiment, the average density of surface defects in the stack structure 20 is 10.0 defects/cm² or less, preferably 7.0 defects/cm² or less, and more preferably 5.0 defects/cm² or less. Now, the average density of surface defects will be described with reference to FIG. 2. FIG. 2 is a diagram for explaining the density of surface defects, and is a schematic diagram when the surface of the stack structure 20 is viewed from above. As illustrated in FIG. 2, the average density of surface defects is obtained by dividing the total number of surface defects present in an internal region 21A (region surrounded by a broken line in the drawing) excluding a width of 5 mm from the outer edge of the surface 21 of the stack structure 20, by the area of the internal region 21A, and indicates the number of surface defects per unit area. In the present embodiment, since the uppermost layer of the stack structure 20 is the cap layer 60, the average density of surface defects on the surface of the cap layer 60 is 10.0 defects/cm² or less. Hereinafter, the density of the surface defects may simply be referred to as defect density, and the average density of the surface defects may also be referred to as an average defect density.

Since the stack structure 20 is formed on the surface-treated principal surface 11, local occurrence of surface defects is suppressed. That is, in the stack structure 20, the occurrence of a region where the density of surface defects is prominently high locally is suppressed. Specifically, the stack structure 20 has a maximum density of 50.0 defects/cm² or less, preferably 30.0 defects/cm² or less, and more preferably 20.0 defects/cm² or less when an internal region excluding a width of 5 mm from an outer edge of the surface thereof is segmented into a plurality of 10 mm-square region segments and a density of the surface defects in each region segment is measured. As illustrated in FIG. 2, for the maximum value of the density of the surface defects, a region having a 10 mm-square is extracted as a region segment 21B (hatched region in the drawing) by segmenting the internal region 21A in a lattice shape, and the maximum value of the density of the surface defects of each region segment 21B is used. A region not satisfying the 10 mm-square, for example, a region existing between the broken line and the region segment 21B in FIG. 2 is excluded from the calculation of the maximum value of the defect density. Meanwhile, the minimum value of the defect density is not particularly limited, but may be 0 defect/cm², for example.

### (Relative Yellow Intensity)

In the group III nitride crystal constituting the stack structure 20, defects may occur due to the surface state of the SiC substrate 10 serving as a base, or impurities may be mixed therein, resulting in significant fluctuation in the crystal quality. In the present embodiment, since the stack structure 20 is formed on the surface-treated SiC substrate 10, occurrence of defects and mixing of impurities are suppressed, and high crystal quality is obtained. In general, the higher the crystal quality of the group III nitride crystal, the more easily the band edge emission having a wavelength corresponding to the band gap is emitted. On the other hand, when the crystal quality is lowered due to defects or impurities, light having a yellow wavelength (yellow light emission) and being longer than the band edge emission is more likely to be emitted. In other words, the intensity of yellow light emission increases according to the crystal quality. In this regard, the stack structure 20 is configured such that the intensity of yellow light emission is low, specifically, the relative yellow intensity is 1.30 or less at the surface center thereof.

Now, the relative yellow intensity will be described.

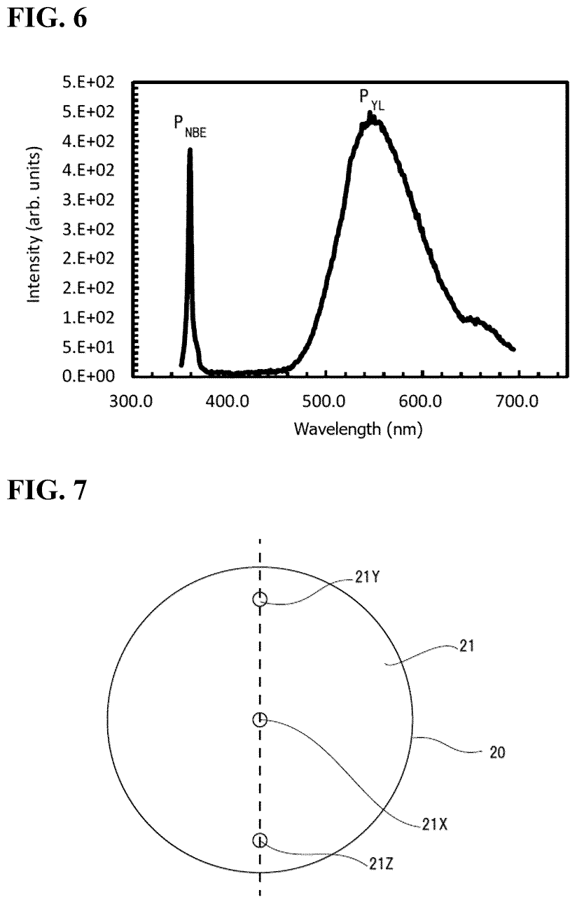

The relative yellow intensity can be calculated from a PL emission spectrum obtained by performing a photoluminescence (PL) mapping measurement on the stack structure 20. In the PL mapping measurement, a measurement position set on the surface of the stack structure 20 is irradiated with laser light from a light source. The irradiation diameter of the laser beam irradiated corresponds to the size of the measurement region. The PL light is emitted from the measurement position by the irradiation of the laser light. The PL light is detected by a detector. As a result, the PL emission spectrum corresponding to the measurement position as illustrated in FIG. 6 can be obtained. FIG. 6 is a schematic diagram of a photoluminescence emission spectrum obtained with a group III nitride crystal. The irradiation diameter of the laser beam may be 1 mm, for example. With such an irradiation diameter, the average crystal quality in the measurement region can be evaluated.

As illustrated in FIG. 6, the PL emission spectrum indicates a correlation between wavelength and intensity, where the horizontal axis represents wavelength [nm] and the vertical axis represents intensity expressed in arbitrary units. The PL emission spectrum has a peak P_{NBE} of band edge emission and a peak P_{YL} of yellow light emission. The peak P_{YL} of yellow light emission is a peak corresponding to a deep level due to low crystallinity of the stack structure 20.

The peak wavelength λ_{NBE} in the peak P_{NBE} of the band edge emission may vary depending on the composition of the group III nitride crystal, and in the case of GaN, for example, the peak wavelength λ_{NBE} is 365 nm, and the energy corresponding thereto is 3.4 eV. The peak wavelength λ_{YL} of the yellow light emission peak P_{YL} may fluctuate depending on the composition of the group III nitride crystal, the growth conditions, and the like, but may be a wavelength in the range of 500 nm or more and 650 nm or less. For example, in the case of GaN, the peak wavelength λ_{YL} is 564 nm, and the energy corresponding thereto is 2.2 eV.

The peak P_{NBE} of the band edge emission and the peak P_{YL} of the yellow light emission each have a predetermined emission intensity. The yellow light emission changes according to the quality of the group III nitride crystal constituting the stack structure 20, and the higher the quality, the lower the emission intensity of the yellow light emission tends to be. That is, as the quality becomes higher, the relative yellow intensity, which is the ratio of the yellow emission intensity to the band edge emission intensity, becomes lower.

As described above, the stack structure 20 has high crystal quality and is configured such that the relative yellow intensity of photoluminescence is 1.30 or less at the sample center. The relative yellow intensity is preferably 1.25 or less, and more preferably 1.20 or less. The surface center of the stack structure 20 indicates the center of the surface of the uppermost layer of the stack structure 20. In the present embodiment, since the uppermost layer of the stack structure 20 is the cap layer 60, the relative yellow intensity at the surface center of the cap layer 60 is 1.30 or less.

The stack structure 20 is configured to have high crystal quality and uniform crystal quality in the layer. That is, in the stack structure 20, the occurrence of a region where the crystal quality is prominently low locally is suppressed. Specifically, the stack structure 20 preferably has a fluctuation rate of the relative yellow intensities (Xₘₐₓ−Xₘᵢₙ)/X_{avg} of 20% or less, where Xₘₐₓ is the maximum value, Xₘᵢₙ is the minimum value, and X_{avg} is the average of the relative yellow intensities taken at three or more points in an internal region of the surface of the stack structure, the internal region excluding a width of 5 mm from the outer edge of the surface, the three or more points being freely selected along a central line of the surface, the three or more points including the center of the surface and two or more points spaced apart from the center. The fluctuation rate is more preferably 15% or less, and still more preferably 10% or less. Since growth in the outer edge region is unstable and crystal quality tends to decrease on the surface of the stack structure 20, the relative yellow intensity may be measured in the internal region excluding the outer edge region, as described in examples described later. The width of the outer edge region is not particularly limited, but may be 5 mm, for example.

The fluctuation rate of the relative yellow intensity can be obtained, for example, as illustrated in FIG. 7. FIG. 7 is a schematic view for explaining a case of calculating the fluctuation rate of the relative yellow intensity, and is a diagram of the stack structure 20 as viewed from above. In FIG. 7, on the surface 21 of the stack structure 20, three points that are a center 21X, and a point 21Y and a point 21Z spaced apart from the center 21X by a predetermined distance, are selected along a central line (broken line in the drawing). In general, the relative yellow intensity tends to be lower toward the center of the stack structure 20 and higher toward the outer edge. Therefore, in the present embodiment, three or more points including the center are selected. Then, the relative yellow intensity at each point is obtained, and Xₘₐₓ, Xₘᵢₙ, and X_{avg} are calculated from these numerical values, whereby the fluctuation rate of the relative yellow intensity can be calculated. When calculating the fluctuation rate, at least three points including the center are to be selected, and four or more points may be selected.

As described above, according to the stack structure 20, which is configured such that the fluctuation rate of the relative yellow intensity is 20% or less, the fluctuation of the relative yellow intensity in the plane of the surface 21 is small, and the crystal quality becomes uniformly high in the layer.

### (2) Method of Manufacturing Group III Nitride Stack

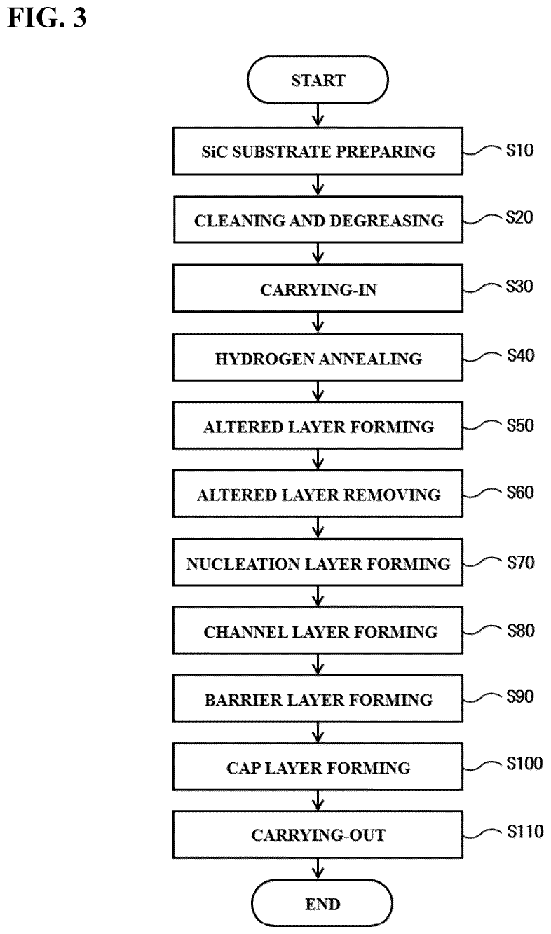

Next, a method of manufacturing the group III nitride stack according to the present embodiment will be described with reference to FIG. 3. FIG. 3 is a flowchart illustrating a method of manufacturing a group III nitride stack according to the present embodiment.

The method of manufacturing a group III nitride stack according to the present embodiment includes, for example, S10 of SiC substrate preparing, S20 of cleaning and degreasing, S30 of carrying-in, S40 of hydrogen annealing, S50 of altered layer forming, S60 of altered layer removing, S70 of nucleation layer forming, S80 of channel layer forming, S90 of barrier layer forming, S100 of cap layer forming, and S110 of carrying-out.

### (S10: SiC Substrate Preparing)

First, a SiC substrate 10 is prepared. As the SiC substrate 10, a substrate may be used in which SiC is exposed on the surface, and no components other than SiC are substantially stacked on the surface. As the SiC substrate 10, for example, a polytype 4H or 6H semi-insulating SiC substrate can be used.

### (S20: Cleaning and Degreasing)

Subsequently, the SiC substrate 10 may be subjected to, for example, known cleaning or degreasing treatment. For cleaning or degreasing, an acid or alkali aqueous solution, an organic solvent, a surfactant, pure water, or the like can be used.

### (S30: Carrying-In)

Subsequently, the SiC substrate 10 having been subjected to cleaning and degreasing is carried into a treatment vessel of a known deposition apparatus. In the present embodiment, the surface treatment including S40 of hydrogen annealing to S60 of altered layer removing described later is performed in a deposition apparatus for performing crystal growth such as S70 of nucleation layer forming to S100 of cap layer forming.

The deposition apparatus includes a treatment vessel, a gas supply mechanism, a susceptor, and a heater. The susceptor is disposed in the treatment vessel, can receive the SiC substrate 10 thereon, and is configured so that the SiC substrate 10 can be heated by a heater. The gas supply mechanism is configured to supply a predetermined treatment gas into the treatment vessel. As the deposition apparatus, either a hot wall type or a cold wall type may be used. A cold wall type treatment apparatus is preferable from the viewpoint of sufficiently increasing the treatment temperature of the surface treatment described later and more reliably performing the surface treatment.

As the deposition apparatus, for example, a metal organic vapor phase epitaxy (MOVPE) apparatus which performs growth by a MOVPE method, a hydride vapor phase epitaxy (HVPE) apparatus which performs growth by a HVPE method, or the like can be used. In the following description, a case where an MOVPE apparatus is used will be described as an example.

### (S40: Hydrogen Annealing)

Next, the SiC substrate 10 placed on the susceptor in the treatment vessel is annealed in a reducing atmosphere. The SiC substrate 10 is heated, for example, in a hydrogen gas (H₂ gas) atmosphere and subjected to a hydrogen annealing treatment. According to the hydrogen annealing treatment, the oxide film (natural oxide film or the like) formed on the surface of the SiC substrate 10 can be removed, and the surface treatment in S50 of altered layer forming and S60 of altered layer removing described later can be performed more reliably. In the hydrogen annealing treatment, the treatment temperature is, for example, 950° C. or higher and 1300° C. or lower, and the treatment time is, for example, 10 seconds or more and 600 seconds or less.

### (S50: Altered Layer Forming)

Next, before growing the group III nitride crystal, a Si-deficient region is formed as an altered layer in the principal surface 11 of the SiC substrate 10. Specifically, the SiC substrate 10 placed on the susceptor is heated to a predetermined temperature by a heater, and a halogen-containing gas is supplied as a treatment gas by a gas supply mechanism. By this supply, silicon (Si) is desorbed from the principal surface 11, and a Si-deficient region can be formed in the principal surface 11. It is presumed that the Si-deficient region is formed when the SiC constituting the principal surface 11 reacts with a halogen-containing gas, generating a silicon halide gas, which leads to the desorption of Si. The carbon (C) remaining in the Si-deficient region may be graphenized.

The Si-deficient region corresponds to a region in the surface layer of the principal surface 11 of the SiC substrate 10. The thickness is not particularly limited as long as it is at least one atomic layer.

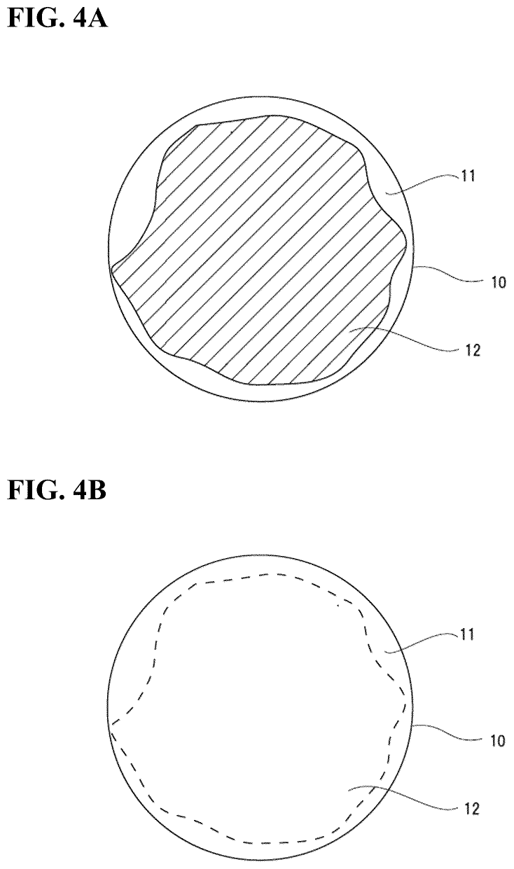

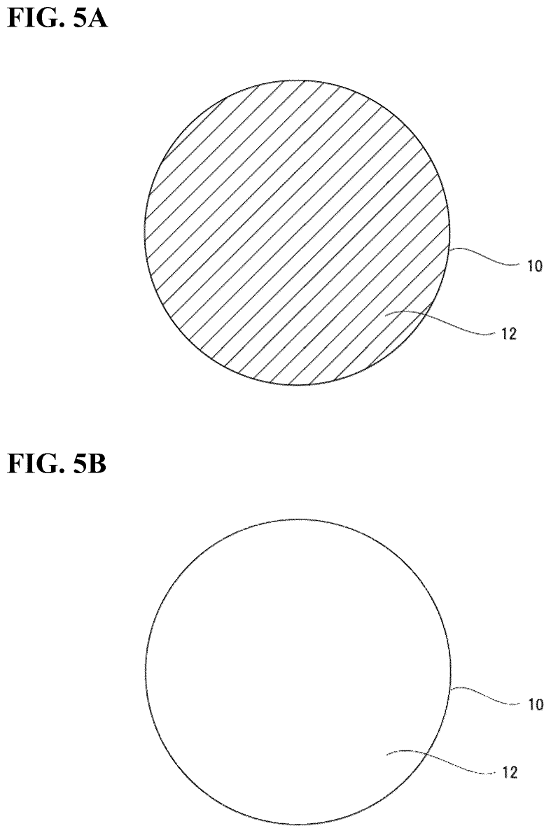

In S50 of altered layer forming, it is preferable to perform the treatment under a condition under which a Si-deficient region is formed over the entire area of the principal surface 11 of the SiC substrate 10. For example, as illustrated in FIG. 4A, when the Si-deficient region 12 is formed in a part of the principal surface 11 of the SiC substrate 10, as illustrated in FIG. 4B, the surface of the part of the principal surface 11 is modified in S60 of altered layer removing described later. When crystal growth is performed on the partially modified principal surface 11, surface defects may locally increase in the unmodified region, and the surface defects may concentrate there. In addition, the quality of the crystal formed on the unmodified region may be lowered. On the other hand, for example, as illustrated in FIG. 5A, when the Si-deficient region 12 is formed over the entire area of the principal surface 11, as illustrated in FIG. 5B, the principal surface 11 can be modified over the entire area in S60 of altered layer removing. As a result, when the stack structure 20 is formed, variation in surface defects in the plane of the stack structure 20 can be suppressed. That is, the in-plane distribution of surface defects can be improved. In addition, the surface defects can be reduced and the average defect density of the stack structure 20 can be lowered. In addition, the crystal quality can be uniformly improved in the layer of the stack structure 20, and the relative yellow intensity and the fluctuation rate thereof can be reduced.

Examples of the treatment conditions of S50 of altered layer forming include a treatment temperature (heating temperature of the SiC substrate 10), treatment time, and the like. The treatment temperature is preferably 850° C. or higher and 1150° C. or lower, and more preferably 900° C. or higher and 1100° C. or lower, from the viewpoint of forming the Si-deficient region over the entire area of the principal surface 11 to suppress variation in the in-plane distribution of surface defects and reduce the relative yellow intensity. The treatment time is preferably, for example, 120 seconds or more and 720 seconds or less. From the viewpoint of forming the Si-deficient region over the entire area of the principal surface 11, it is preferable to control the above-described treatment temperature so as to be uniform over the entire surface of the SiC substrate 10.

In S50 of altered layer forming, the halogen-containing gas may be mixed with an inert gas such as nitrogen gas (N₂) to adjust reactivity. In the treatment vessel, the supplied halogen-containing gas is mixed with a carrier gas or the like and diluted to a predetermined concentration. The concentration of the halogen-containing gas refers to a molar ratio of the halogen-containing gas in the atmosphere in the reaction vessel. The concentration is not particularly limited, but is preferably 0.1% or more and less than 2%, and more preferably 0.1% or more and 1.5% or less, from the viewpoint of preventing Si from being excessively desorbed in the thickness direction while Si is desorbed over the entire area of the principal surface 11 of the SiC substrate 10.

As the halogen-containing gas, at least one gas selected from the group consisting of F₂ gas, Cl₂ gas, Br₂ gas, I₂ gas, NF₃ gas, ClF₃ gas, HF gas, HCl gas, HBr gas, and HI gas is preferably used. With these gases, Si can be desorbed from SiC, and a Si-deficient region can be formed more reliably. As the atmosphere gas for the Si desorption treatment, for example, nitrogen gas (N₂ gas) may be used.

### (S60: Altered Layer Removing)

Subsequently, the Si-deficient region as an altered layer is removed from the principal surface 11 of the SiC substrate 10 in the same treatment vessel of the MOVPE apparatus. Here, since the inside of the treatment vessel is in the halogen-containing gas atmosphere due to S50 of altered layer forming, for example, after the inside of the treatment vessel is replaced with N₂ gas, the hydrogen-containing gas is supplied as the treatment gas into the treatment vessel by the gas supply mechanism while heating the SiC substrate 10. By this supply, the Si-deficient region formed in the surface of the principal surface 11 is removed. The removal of the Si-deficient region is presumed to occur by the reaction of the C components contained in the Si-deficient region with hydrogen-containing gas, generating hydrocarbon gas, which leads to the desorption of C. Since the Si-deficient region can be a factor causing surface defects, by removing the Si-deficient region, the occurrence of surface defects can be suppressed, and the crystal quality of the stack structure 20 can be uniformly improved. Note that the gas in the treatment vessel may be replaced by, for example, stopping the supply of the halogen-containing gas, temporarily increasing the pressure while increasing the temperature in the treatment vessel, and then decreasing the pressure again.

In S60 of altered layer removing, it is preferable to perform the treatment under a condition under which the Si-deficient region is removed from the entire area of the principal surface 11. Accordingly, the Si-deficient region is removed over the entire area of the principal surface 11, and the occurrence of surface defects and the decrease in crystal quality due to the Si-deficient region can be suppressed. As a result, the average defect density of the stack structure 20 can be reduced, and the local distribution (concentration) of surface defects can be suppressed. Further, the relative yellow intensity of the stack structure 20 and the fluctuation rate thereof can be suppressed to be low.

Examples of the treatment conditions of S60 of altered layer removing include a treatment temperature (heating temperature of the SiC substrate 10), treatment time, and the like. From the viewpoint of removing the Si-deficient region from the entire area of the principal surface 11, the treatment temperature is preferably 1050° C. or higher and 1250° C. or lower, and more preferably 1100° C. or higher and 1200° C. or lower. The treatment time is preferably, for example, 150 seconds or more and 600 seconds or less. From the viewpoint of removing the Si-deficient region over the entire area of the principal surface 11, it is preferable to control the above-described treatment temperature to be uniform over the entire surface of the SiC substrate 10.

From the viewpoint of more reliably removing the Si-deficient region, the treatment temperature of S60 of altered layer removing is preferably higher than the treatment temperature of S50 of altered layer forming. As a result, the desorption of C is promoted, and the Si-deficient region can be more reliably removed. By making the treatment temperature relatively low in S50 of altered layer forming, excessive desorption of Si on the surface of the SiC substrate 10 can be suppressed, and by making the treatment temperature relatively high in S60 of altered layer removing, the Si-deficient region formed in S50 of altered layer forming can be more reliably removed.

From the viewpoint of suitably removing the Si-deficient region, at least one gas selected from the group consisting of H₂ gas, NH₃ gas, N₂H₂ gas, N₂H₄ gas, and N₃H₈ gas is preferably used as the hydrogen-containing gas. For example, N₂ gas or H₂ gas may be used as the atmosphere gas for the Si-deficient region removal treatment.

### (S70: Nucleation Layer Forming)

Next, a group III nitride crystal is grown on the principal surface 11 of the SiC substrate 10 in the treatment vessel, subsequent to S60 of altered layer removing. Here, for example, a single crystal of AlN is heteroepitaxially grown to form the nucleation layer 30. Since the principal surface 11 of the SiC substrate 10 is surface-modified by the surface treatment, the nucleation layer 30 having high crystal quality can be formed.

When the nucleation layer 30 is formed of AlN, for example, trimethylaluminum (TMA) gas is used as the group III (Al) source gas. As the N source gas, for example, NH₃ gas is used. These source gases may be mixed with a carrier gas using a hydrogen (H₂) gas, a nitrogen (N₂) gas, or a mixed gas thereof and supplied.

Examples of the crystal growth conditions for forming the nucleation layer 30 include a growth temperature, a V/III ratio, and a growth pressure, which may be set to conventionally known values. Here, the “V/III ratio” is a ratio of the supply amount (partial pressure) of the group V (N) source gas to the supply amount (partial pressure) of the group III (Al) source gas.

### (S80: Channel Layer Forming)

Next, a group III nitride crystal is grown on the upper surface of the nucleation layer 30 in the same treatment vessel of the MOVPE apparatus. Here, for example, a single crystal of GaN is heteroepitaxially grown to form the channel layer 40.

When the channel layer 40 is formed of GaN, for example, trimethylgallium (Ga(CH₃)₃, TMG) gas is used as the group III (Ga) source gas. As the N source gas, for example, NH₃ gas is used. These source gases may be mixed with a carrier gas using a hydrogen (H₂) gas, a nitrogen (N₂) gas, or a mixed gas thereof and supplied.

Examples of the crystal growth conditions for forming the channel layer 40 include a growth temperature, a V/III ratio, and a growth pressure, which may be set to conventionally known values.

### (S90: Barrier Layer Forming)

Next, in the same treatment vessel of the MOVPE apparatus, a single crystal of a group III nitride having an electron affinity smaller than that of a group III nitride crystal constituting the channel layer 40 is heteroepitaxially grown on the upper surface of the channel layer 40 to form a barrier layer 50.

When the barrier layer 50 is formed of, for example, a single crystal of AlN, AlGaN, InAlN, or AlInGaN, for example, trimethylaluminum (Al(CH₃)₃, TMA) gas is used as the Al source gas. As the In source gas, for example, trimethylindium (In(CH₃)₃, TMI) gas is used. For other gases, gases similar to those used in S80 of channel layer forming are employed.

### (S100: Cap Layer Forming)

Next, in the same treatment vessel of the MOVPE apparatus, for example, GaN as a group III nitride single crystal is heteroepitaxially grown on the upper surface of the barrier layer 50 to form a cap layer 60.

(S110: Carrying-out)

Subsequently, the stack 1 is carried out from the treatment vessel. The stack 1 of the present embodiment is obtained in the way described above.

### (3) Effects Obtained by Present Embodiment

According to the present embodiment, one or more effects described below can be obtained.

(a) In the SiC substrate 10, even if cleaning, degreasing, and hydrogen annealing are performed before crystal growth to improve the state of the surface serving as a base, surface defects may not be stably reduced in some cases when the stack structure 20 is formed. As described above, the surface state (surface roughness, difference in polytype, etc.), density of dislocations, etc. of the SiC substrate 10 are considered as the cause of occurrence of surface defects, and it is presumed that these effects cannot be sufficiently suppressed by cleaning, degreasing, etc. In this regard, in the present embodiment, before growing the group III nitride crystal on the principal surface 11 of the SiC substrate 10, the Si-deficient region is formed and removed in advance as an altered layer on the SiC substrate 10. In S50 of altered layer forming, Si is desorbed from the principal surface 11 of the SiC substrate 10 by supplying the halogen-containing gas, and a Si-deficient region is formed in the principal surface 11. In S60 of altered layer removing, the Si-deficient region is removed by supplying the hydrogen-containing gas. Thus, the principal surface 11 can be modified at the atomic layer level. By performing crystal growth on the surface-modified principal surface 11, the average defect density of the stack structure 20 can be reduced. In addition, local occurrence and uneven distribution of surface defects in the stack structure 20 can be suppressed.

(b) The stack structure 20 of the stack 1 is formed by growing a group III nitride crystal on the principal surface 11 subjected to the surface treatment illustrated in the above-described (a), so that the average defect density on the surface becomes 10.0 defects/cm² or less, and the maximum value of the defect density among the respective region segments 21B when segmenting the internal region 21A becomes 50.0 defects/cm² or less. According to such a stack 1, since the average defect density is low, high device characteristics can be realized when a semiconductor device is fabricated. Further, since the maximum value of the defect density in the plane is low and the uneven distribution of the surface defects is suppressed, the yield of the semiconductor device can be improved.

(c) It is preferable that S60 of altered layer removing be performed under a condition under which the Si-deficient region as the altered layer is removed from the entire area of the principal surface 11. As a result, Si-deficient regions that may cause surface defects can be removed, and the average defect density and the maximum value of surface defects can be further reduced. Specifically, the average defect density of the stack structure 20 can be 7.0 defects/cm² or less, and the maximum value of the defect density can be 30.0 defects/cm² or less.

(d) In addition, in the SiC substrate 10, even if cleaning, degreasing, and hydrogen annealing are performed before crystal growth, the crystal quality may not be stably increased when the stack structure 20 is formed. According to studies by the present inventors, it has been found that this problem hardly occurs in a GaN substrate or the like, and is peculiar to the SiC substrate 10. In this regard, in the present embodiment, before growing the group III nitride crystal on the principal surface 11 of the SiC substrate 10, the Si-deficient region is formed and removed in advance as an altered layer on the SiC substrate 10. In S50 of altered layer forming, Si is desorbed from the principal surface 11 of the SiC substrate 10 by supplying the halogen-containing gas, and a Si-deficient region is formed in the principal surface 11. In S60 of altered layer removing, the Si-deficient region is removed by supplying the hydrogen-containing gas. Thus, the principal surface 11 can be modified at the atomic layer level. By performing crystal growth on the surface-modified principal surface 11, the crystal quality of the stack structure 20 can be improved, and the occurrence of regions where the crystal quality is locally lowered can be suppressed.

(e) The stack structure 20 of the stack 1 is formed by growing a group III nitride crystal on the principal surface 11 to which the surface treatment illustrated in the above-described (d) is applied, so that the relative yellow intensity becomes 1.30 or less at the surface center thereof. Further, when three or more points including the center of the surface are selected, the fluctuation rate of the relative yellow intensities thereof is 20% or less. According to such a stack 1, since the stack 1 has such a high crystal quality that yellow light emission is suppressed, high device characteristics can be realized when a semiconductor device is fabricated. In addition, since the crystal quality is uniformly high in the layer and the occurrence of a locally low crystal quality region is suppressed, the yield of the semiconductor device can be improved.

(f) It is preferable that S60 of altered layer removing be performed under a condition under which the Si-deficient region as the altered layer is removed from the entire area of the principal surface 11. As a result, the Si-deficient region that may degrade the crystal quality can be removed, and the relative yellow intensity and the fluctuation rate thereof can be further reduced. Specifically, the relative yellow intensity at the surface center of the stack structure 20 can be set to 1.25 or less, and the fluctuation rate thereof can be set to 15% or less.

(g) From the viewpoint of achieving the effect of the above-described (c) or (f) more reliably, it is preferable to set the treatment temperature in S60 of altered layer removing to 1050° C. or higher and 1250° C. or lower. The treatment time is preferably 150 seconds or more and 600 seconds or less.

(h) In addition, along with the above-described treatment (c) or (f), it is preferable to perform S50 of altered layer forming under a condition under which a Si-deficient region is formed over the entire area of the principal surface 11 of the SiC substrate 10. This enables modification of the entire area of the principal surface 11. Therefore, surface defects can be uniformly reduced on the surface of the stack structure 20, and local occurrence of surface defects can be more reliably suppressed. Specifically, the average defect density of the stack structure 20 can be 5.0 defects/cm² or less, and the maximum value of the defect density can be 20.0 defects/cm² or less. In addition, the crystal quality can be further improved on the surface of the stack structure 20, and the occurrence of a region where the crystal quality is locally lowered can be more reliably reduced. Specifically, the relative yellow intensity at the surface center of the stack structure 20 can be set to 1.20 or less, and the fluctuation rate thereof can be set to 10% or less.

(i) From the viewpoint of achieving the effect of the above-described (h) more reliably, it is preferable to set the treatment temperature in S50 of altered layer forming to 850° C. or higher and 1150° C. or lower. The treatment time is preferably 120 seconds or more and 720 seconds or less.

(j) The treatment temperature in S60 of altered layer removing is preferably higher than that in S50 of altered layer forming. Accordingly, the activity of C desorption can be enhanced in S60 of altered layer removing while suppressing excessive formation of the Si-deficient region as an altered layer, and the formed Si-deficient region can be removed more reliably.

(k) The surface treatment including S50 of altered layer forming and S60 of altered layer removing and the crystal growth of the stack structure 20 are preferably consecutively performed in the same deposition apparatus. As a result, productivity in manufacturing the stack 1 can be improved. In addition, contamination of the SiC substrate 10 due to atmospheric exposure can be avoided, and the occurrence of surface defects can be further suppressed. As a result, the device characteristics and reliability of the semiconductor device manufactured using the stack 1 can be improved.

### Other Embodiments

The embodiments of the present disclosure have been specifically described above. However, the present disclosure is not limited to the above-described embodiments, and various modifications can be made without departing from the scope of the present disclosure.

In the above-described embodiment, the stack 1 includes the stack structure 20 including the nucleation layer 30, the channel layer 40, the barrier layer 50, and the cap layer 60, but the present disclosure is not limited thereto. For example, the stack structure 20 may be formed by stacking the nucleation layer 30 and the channel layer 40. For example, the stack structure 20 may be configured by stacking the nucleation layer 30, the channel layer 40, and the barrier layer 50. For example, the stack structure 20 may be configured such that an AlN layer is interposed between the channel layer 40 and the barrier layer 50. For example, the stack structure 20 may be configured such that an InGaN layer or AlGaN is interposed in the channel layer 40. In any case, a surface defect may occur on the surface of the layer constituting the uppermost surface of the stack structure 20 depending on the surface state of the base substrate, but the occurrence of the surface defect can be suppressed by forming and removing the altered layer, and the average defect density and the maximum value of the defect density in the layer constituting the uppermost surface satisfy the predetermined value. In any case, since the crystal quality of the stack structure 20 becomes high, the relative yellow intensity and the fluctuation rate thereof satisfy the predetermined values in the layer constituting the uppermost surface.

In the above-described embodiment, the nucleation layer 30 and the channel layer 40 are grown by an MOVPE method, but one or both of them may be grown by, for example, a hydride vapor phase epitaxy (HVPE) method.

The Si desorption treatment and the Si-deficient region removal treatment may be alternately performed over a plurality of times. Although desired effects can be obtained even when these treatments are performed only once, by repeating these treatments, the principal surface 11 of the SiC substrate 10 can be surface-treated more reliably, and the crystal quality can be improved more reliably.

### Examples

Next, examples according to the present disclosure will be described. These examples are merely examples of the present disclosure, and the present disclosure is not limited to these examples.

In the present example, a group III nitride stack was fabricated, and the defect density on the surface and the relative yellow intensity on the surface were evaluated. Hereinafter, specific description will be given.

### (1) Fabrication of Group III Nitride Stack

In the present example, first, a SiC substrate was prepared. Subsequently, the SiC substrate was cleaned and degreased. The degreased SiC substrate was introduced into a treatment vessel of an MOVPE apparatus. Subsequently, in the hydrogen annealing, the SiC substrate was heated in an H₂ gas atmosphere in the treatment vessel. Subsequently, in the altered layer forming, the inside of the treatment vessel was set to an N₂ gas atmosphere, the SiC substrate was heated at a predetermined treatment temperature, and Cl₂ gas was supplied as a chlorine-containing gas. At this time, the supply amount of the Cl₂ gas was adjusted so that the concentration of the Cl₂ gas in the atmosphere in the treatment vessel was 1.1%. Thus, Si was desorbed from the principal surface of the SiC substrate, and a Si-deficient region was formed as an altered layer on the surface of the SiC substrate. After the altered layer forming, the inside of the treatment vessel was replaced with an inert gas. Subsequently, in the altered layer removing, the inside of the treatment vessel was set to an N₂ gas atmosphere, the SiC substrate was heated at a predetermined treatment temperature, and NH₃ gas was supplied as a hydrogen-containing gas. Thus, C was desorbed from the principal surface of the SiC substrate to remove the Si-deficient region. Subsequently, in the same treatment vessel, a stack structure constituted from a nucleation layer, a channel layer, a barrier layer, and a cap layer was crystal-grown on the principal surface of the SiC substrate under the following growth conditions to fabricate a stack. In the present example, the treatment temperature and the treatment time of the altered layer forming and the altered layer removing were appropriately changed as shown in Table 1 described below, and stacks of Samples 1 to 3 were fabricated. The stack of Sample 4 was fabricated in the similar manner as in Samples 1 to 3 except that the altered layer forming and the altered layer removing were not performed.

The SiC substrate, the treatment conditions of the hydrogen annealing treatment, and the growth conditions of each layer of the stack structure are as follows.

### (SiC Substrate)

Material: SiC (semi-insulating)
Diameter: 6 inches
Thickness: 500 μm
Low-index crystal plane closest to the base surface: c-plane (no patterning of base surface)
Polytype: 6H

### (Treatment Conditions in Hydrogen Annealing)

Treatment temperature: 950° C. to 1300° C.
Treatment time: 10 seconds to 600 seconds
Gas atmosphere: H₂ Gas

### (Nucleation Layer Growth Conditions)

Material: AlN
Growth method: MOVPE method
Growth temperature: 1200° C. to 1290° C.

1Designed film thickness: 10 nm to 13 nm
V/III Ratio: 5000 to 25000
Growth Pressure: 0.059 atm to 0.098 atm

### (Channel Layer Growth Conditions)

Material: GaN
Growth method: MOVPE method
Growth temperature: 1100° C. to 1200° C.
V/III Ratio: 1000 to 3000
Growth pressure: 0.098 atm to 0.197 atm
Designed film thickness: 400 nm

### (Barrier Layer Growth Conditions)

Material: AlGaN
Growth method: MOVPE method
Growth temperature: 1100° C. to 1200° C.
Growth pressure: 0.098 atm to 0.197 atm
Designed film thickness: 20 nm
(Cap Layer)
Material: GaN
Growth method: MOVPE method
Designed film thickness: 2 nm

### (2) Evaluation

### (Surface Defects)

With respect to the fabricated Samples 1 to 4, surface defects on the surface of the stack structure were detected, and the average density and the in-plane distribution of the surface defects were evaluated. Specifically, the entire surface of the stack was irradiated with a laser beam using a wafer surface inspection apparatus (“YPI-MX-θ” manufactured by YGK Corporation), and surface defects were detected from the reflection and scattering of the laser beam. In the present example, as the surface defect, a defect having a size of 0.165 μm or more and 2.0 μm or less when viewed from the surface was detected. When detecting surface defects, the wavelength of laser light was set to 375 nm, and a photomal was employed as a detector. The surface defects were detected in an environment where the number of external particles was less than 1.0 particles/cm³.

As illustrated in FIG. 2, the average density of the surface defects was calculated by obtaining the total number of the surface defects in the internal region 21A of the surface 21 of the stack structure 20 excluding the range of the width of 5 mm from the outer shape thereof and dividing the total number by the area of the internal region 21A.

The in-plane distribution of surface defects was calculated as follows. Specifically, first, as illustrated in FIG. 2, the internal region 21A was segmented into 10 mm-square region segments 21B. Here, the region not satisfying the 10 mm-square was excluded, and 129 region segments 21B were obtained. Subsequently, the total number of surface defects was obtained for each region segment 21B, and the defect density was calculated by dividing the total number by the area. Then, the minimum value and the maximum value of the defect densities of the respective region segments 21B were obtained.

### (Relative Yellow Intensity)

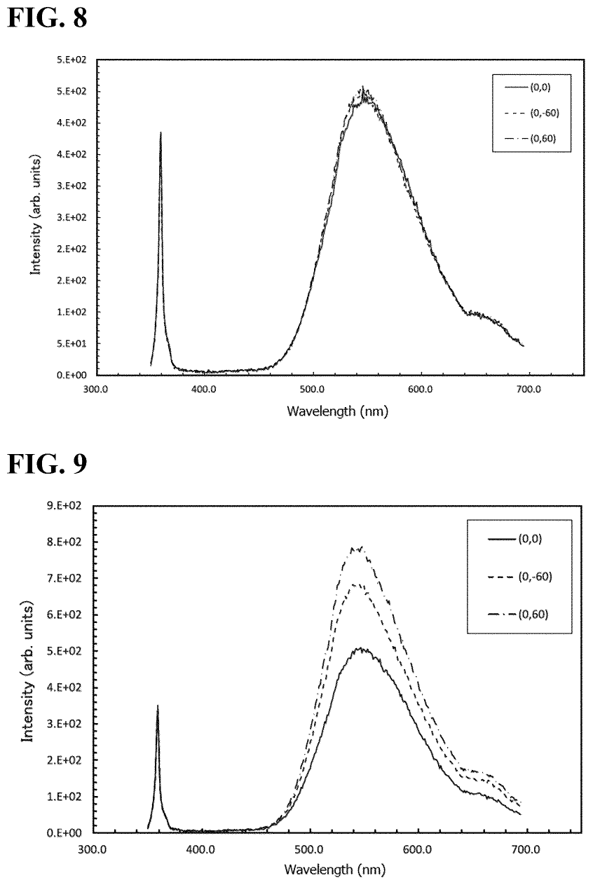

With respect to Samples 1 to 4, the relative yellow intensity on the surface of the stack structure and the fluctuation rate thereof were evaluated. Here, a photoluminescence (PL) measurement apparatus (“Photoluminor-D” manufactured by HORIBA, Ltd.) was used to measure the relative yellow intensity and the fluctuation rate thereof. Specifically, first, on the surface of the stack, three points, i.e., a center (point A), a point (point B) spaced apart from the point A by 60 mm toward the outer edge side, and a point (point C) spaced apart from the point A by 60 mm toward the opposite side to the point B, were selected as measurement positions along the central line. Next, each measurement position was irradiated with laser light using a PL measurement apparatus, and PL emission spectra were obtained. PL emission spectra of the samples are illustrated in FIGS. 8 and 9. FIG. 8 and FIG. 9 illustrate emission spectra measured at three points of Sample 1 and Sample 4, respectively. In each of the drawings, (0, 0) represents a PL emission spectrum at a point A, i.e., the center, (0, 60) represents a PL emission spectrum at a point B, and (0,−60) represents a PL emission spectrum at a point C. From the emission spectrum, the relative yellow intensity at the measurement position and the fluctuation rate of the relative yellow intensity were calculated for each sample.

In the PL measurement, a He—Cd laser was used, the laser wavelength was 325 nm, the laser output was 25 to 30 mW, and the irradiation diameter of the laser beam was 1 mm.

(3) Evaluation Results The results of the above evaluations are summarized in Table 1.

TABLE 1

| | | | Sample 1 | Sample 2 | Sample 3 | Sample 4 |
|---|---|---|---|---|---|---|
| Altered | Treatment temperature [° C.] | | 970 | 890 | 870 | — |
| layer | Treatment time [s] | | 420 | 420 | 420 | — |
| forming | | | | | | |
| Altered | Treatment temperature [° C.] | | 1100 | 1120 | 1050 | — |
| layer | Treatment time [s] | | 300 | 300 | 300 | — |
| removing | | | | | | |
| Evaluation | Average density of surface defects | | 4.74 | 6.68 | 9.92 | 16.46 |
| | in entire surface [defects/cm²] | | | | | |
| | Minimum value of density of | | 0 | 0 | 2 | 2 |
| | surface defects [defects/cm²] | | | | | |
| | Maximum value of density of | | 18 | 29 | 48 | 109 |
| | surface defects [defects/cm²] | | | | | |
| | Relative | Point X (center) | 1.11 | 1.24 | 1.29 | 1.51 |
| | yellow intensity | Point Y (0, 60) | 1.2 | 1.44 | 1.53 | 2.08 |
| | | Point Z (0, −60) | 1.23 | 1.44 | 1.59 | 2.11 |

| | | | | |
|---|---|---|---|---|
| Fluctuation rate of relative | 10 | 15 | 20 | 32 |
| yellow intensities [%] | | | | |

As illustrated in Table 1, in Samples 1 to 3, it was confirmed that the average density of surface defects in the entire surface of the stack structure can be reduced by forming an altered layer (forming a Si-deficient region by Si desorption) in advance and removing the altered layer (removing a Si-deficient region by C desorption) before crystal growth. In addition, it was confirmed that the relative yellow intensity at the surface center (point A) of the stack structure and the fluctuation rate calculated from the relative yellow intensities at a plurality of points (points A to C) can be reduced.

On the other hand, in Sample 4, although cleaning, degreasing, and hydrogen annealing were performed, crystal growth was performed without forming and removing an altered layer, and therefore, it was confirmed that the average density was higher than those of Samples 1 to 3. In Samples 1 to 3, the maximum value of the density of surface defects was lower than that of Sample 4, indicating that there were fewer regions with many localized surface defects. Further, in Sample 4, it was confirmed that the relative yellow intensity and the fluctuation rate thereof were higher than those of Samples 1 to 3.

As described above, in Samples 1 to 3, it was confirmed that the in-plane distribution can be improved while the average density is reduced, and the crystal quality of the stack structure can be increased and the occurrence of regions where the crystal quality was locally lowered can be suppressed.

In Sample 2, it was confirmed that the in-plane distribution of the defect density can be further improved by reducing the maximum value of the defect density while reducing the average defect density as compared with Sample 3. In Sample 2, it was confirmed that the relative yellow intensity and the fluctuation rate thereof can be further reduced as compared with Sample 3. This is presumably because removal of the altered layer in Sample 2 was further promoted by setting the treatment temperature in the altered layer removing to 1120° C., which is higher than 1050° C. in Sample 3. That is, it is presumed that in Sample 2, the surface treatment could be performed more widely while suppressing the remaining of the altered layer on the principal surface of the SiC substrate than Sample 3.

Further, in Sample 1, it was confirmed that the in-plane distribution of the defect density can be further improved by reducing the maximum value of the defect density while reducing the average defect density as compared with Sample 2. In Sample 1, it was confirmed that the relative yellow intensity and the fluctuation rate thereof could be further reduced as compared with Sample 2. This is presumably because, by setting the treatment temperature of the altered layer forming to 970° C., which is higher than 890° C. in Sample 2, an altered layer can be formed over the entire area of the principal surface of the SiC substrate, and all of the formed altered layer can be removed. That is, it is presumed that in Sample 1, the surface treatment of the principal surface of the SiC substrate can be more reliably performed over the entire area as compared with Sample 2.

As described above, it was confirmed that, by modifying the principal surface of the SiC substrate by the surface treatment, when the stack structure is crystal-grown on the principal surface, the average defect density in the entire surface of the stack structure can be reduced, and the in-plane distribution of surface defects can also be improved. In addition, it was confirmed that the crystal quality of the stack structure can be improved, and the occurrence of a region where the crystal quality is locally lowered can be suppressed.

### Second Embodiment

A method of manufacturing a regenerated SiC substrate according to a second embodiment of the present disclosure will be described. A group III nitride such as gallium nitride (GaN) is used as a material for manufacturing semiconductor devices such as light emitting elements and transistors. A sapphire substrate, a silicon carbide (SiC) substrate, or the like is used as a growth base substrate for epitaxially growing a group III nitride.

Due to various circumstances, it is desired, in some cases, to regenerate the growth base substrate once used for the growth of the group III nitride so that the growth base substrate can be used for the growth of the group III nitride again (for example, for the regeneration of a sapphire substrate, refer to Japanese Patent Laid Open Publication No. 2018-107169). The growth base substrate is preferably regenerated so that the crystal quality of the group III nitride to be grown again is good.

A method of manufacturing a regenerated SiC substrate according to the present embodiment includes: preparing a SiC substrate having a group III nitride adhered on a principal surface; removing the group III nitride from the principal surface by supplying a halogen-containing gas onto the SiC substrate; and supplying a hydrogen-containing gas to the SiC substrate from which the group III nitride has been removed to modify the principal surface.

Here, the group III nitride preferably contains indium (In), aluminum (Al), or gallium (Ga) as a group III element, and is represented by a composition formula of InₓAl_{y}Ga_{(1-x-y)}N (0≤x≤1, 0≤y≤1, x+y≤1).

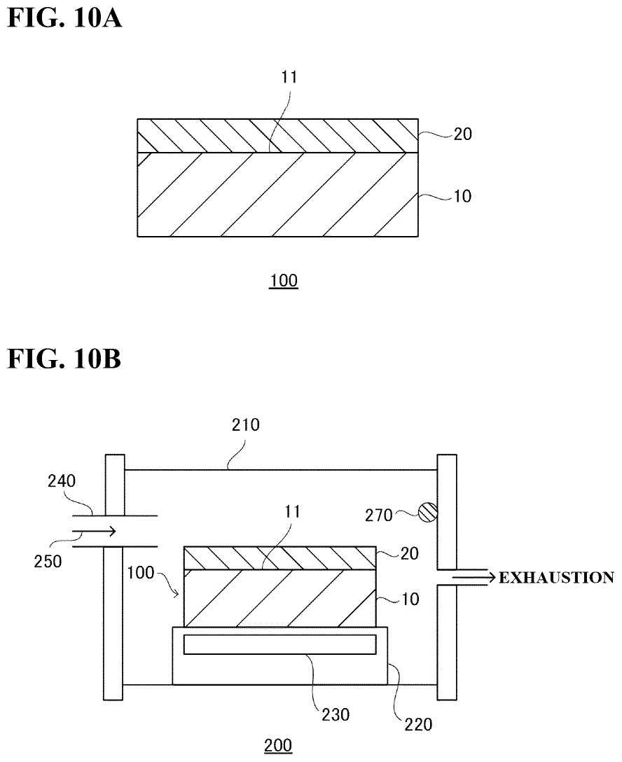

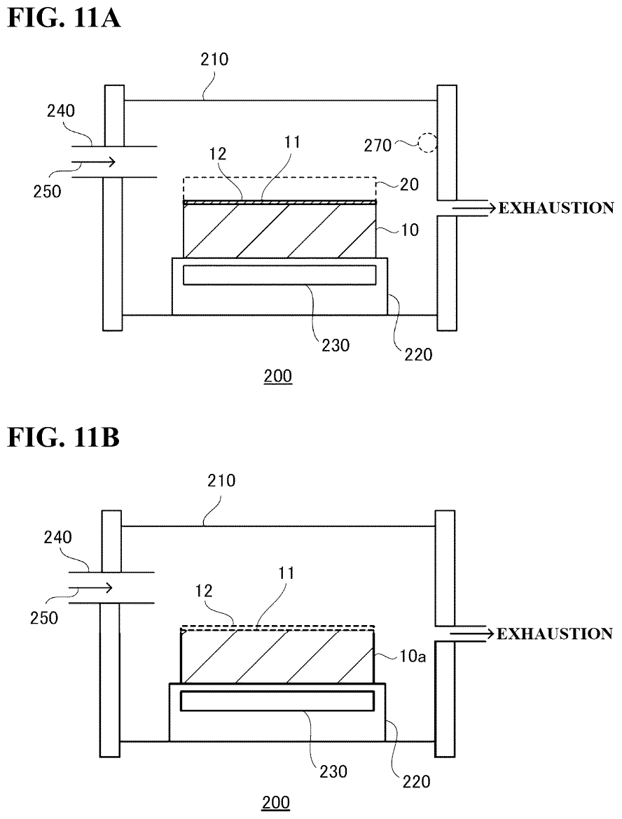

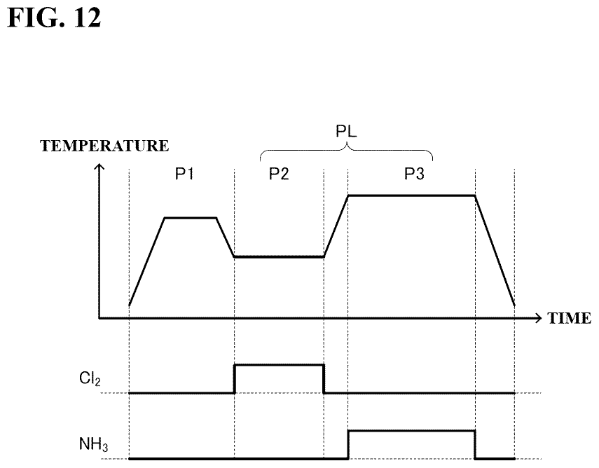

FIGS. 10A to 11B are schematic diagrams illustrating a flow of a regeneration treatment of the SiC substrate 10. FIG. 12 is a timing chart of temperature and gas supply in the regeneration treatment of the SiC substrate 10. FIG. 10A is a schematic view illustrating preparing the SiC substrate 10 (stack structure 100) on which group III nitride is adhered (layer 20 constituted from a group III nitride is formed (deposited)) on the principal surface 11. The SiC substrate 10 is typically prepared in the form of a stack structure 100 having the SiC substrate 10 and a layer 20 constituted from a group III nitride epitaxially grown on the principal surface 11 of the SiC substrate 10. In the present embodiment, the term “principal surface” related to the SiC substrate 10 refers to the upper surface of the SiC substrate 10 (the surface serving as the growth base of the layer 20) rather than the crystal growth surface of the layer 20 (the outermost surface of the stack structure 100).

The layer 20 is typically formed on the entire area of the principal surface 11 of the SiC substrate 10. The structure of the layer 20 is not particularly limited, may be a single layer structure or a stack structure including a plurality of layers, and may have dips and bumps for forming a semiconductor device. The layer 20 may include, for example, a GaN layer, and in embodiments including a GaN layer, may include a buffer layer (e.g., an AlN layer) between the SiC substrate 10 and the GaN layer. The thickness of the layer 20 is, for example, not less than 100 nm and not more than 5000 nm.

FIG. 10B is a schematic diagram illustrating carrying the stack structure 100 into the treatment apparatus 200 and performing a pretreatment prior to the treatment of removing the layer 20. In the present embodiment, a deposition apparatus capable of performing a treatment of growing a group III nitride on the SiC substrate 10 is used as the treatment apparatus 200 that performs a treatment of removing the layer 20 (the group III nitride) to regenerate the SiC substrate 10. For example, a metal organic vapor phase epitaxy (MOVPE) apparatus is used.

As the treatment apparatus 200, either a hot wall type or a cold wall type may be used. However, from the viewpoint of sufficiently increasing the treatment temperature of various types of treatments in the regeneration treatment described below to further enhance the effect of the present embodiment, it is preferable to use the cold wall type treatment apparatus 200. Hereinafter, the cold wall type treatment apparatus 200 will be described as an example.

A susceptor 220 is provided in the treatment vessel 210 of the treatment apparatus 200. The stack structure 100 is placed on the susceptor 220. The susceptor 220 has a heater 230, and the heater 230 heats the stack structure 100 to a predetermined treatment temperature. A gas supply mechanism 240 supplies a treatment gas 250 used for each treatment into the treatment vessel 210.

After the stack structure 100 is carried into the treatment vessel 210, annealing the SiC substrate 10 in a reducing atmosphere is performed as a pretreatment prior to the treatment of removing the layer 20. Specifically, for example, the temperature is increased in a hydrogen gas (H₂ gas) atmosphere, and hydrogen annealing is performed (see a period P1 in FIG. 12). In the annealing treatment, the treatment temperature is, for example, 900° C. or higher and 1300° C. or lower, and the treatment time is, for example, 10 seconds or more and 600 seconds or less.

By the annealing treatment, the oxide film (natural oxide film or the like) formed on the surface (of the group III nitride) of the layer 20 can be removed, and the removal of the group III nitride to be performed thereafter can be proceeded reliably and efficiently.

FIG. 11A is a schematic diagram illustrating supplying a halogen-containing gas to the SiC substrate 10 to remove the layer 20 (group III nitride) from principal surface 11 of the SiC substrate 10. Specifically, for example, dry etching of the layer 20 is performed under predetermined treatment conditions using chlorine gas (Cl₂ gas) as the halogen-containing gas (see a period P2 in FIG. 12). In the removal treatment of the layer 20, the treatment temperature is, for example, 800° C. or higher and 1100° C. or lower (preferably 800° C. or higher and 1000° C. or lower), and the treatment time is, for example, 120 seconds or more and 720 seconds or less. As the atmosphere gas, for example, nitrogen gas (N₂ gas) is used.

In the removal treatment of the layer 20, the entire thickness of the layer 20 is removed to expose the entire area of the principal surface 11 of the SiC substrate 10. Then, silicon (Si) is desorbed from the principal surface 11 exposed by removing the layer 20, and the Si-deficient region 12 is formed in the principal surface 11 (preferably, in the entire area of the principal surface 11). It is understood that SiC constituting the exposed principal surface 11 reacts with a halogen-containing gas to generate a silicon halide gas, whereby Si is desorbed to form the Si-deficient region 12. The carbon (C) remaining in the Si-deficient region 12 may be graphenized

The removal treatment of the layer 20 is preferably performed under a condition under which the Si-deficient region 12 can be formed over the entire area of the principal surface 11. The conditions include, for example, a treatment temperature, a treatment time, and the like. For example, by setting the treatment temperature to a temperature of 800° C. or higher and 1100° C. or lower (preferably 800° C. or higher and 1000° C. or lower) as described above, the Si-deficient region 12 can be formed in substantially the entire region (for example, a region of 90% or more) of the principal surface 11.

From the viewpoint of suitably removing the group III nitride and forming the Si-deficient region 12, at least one gas selected from the group consisting of F₂ gas, Cl₂ gas, Br₂ gas, I₂ gas, NF₃ gas, CIF₃ gas, HF gas, HCl gas, HBr gas, and HI gas may be used as the halogen-containing gas.

FIG. 11B is a schematic diagram illustrating supplying a hydrogen-containing gas to the SiC substrate 10 from which the layer 20 (group III nitride) has been removed to modify the principal surface 11. Specifically, for example, ammonia gas (NH₃ gas) is used as the hydrogen-containing gas, and the principal surface 11 is modified under predetermined treatment conditions (see a period P3 in FIG. 12). In the modification treatment of principal surface 11, the treatment temperature is, for example, 900° C. or higher and 1200° C. or lower (preferably 1100° C. or higher and 1200° C. or lower), and the treatment time is, for example, 150 seconds or more and 600 seconds or less. As the atmosphere gas, for example, N₂ gas or H₂ gas is used. The treatment temperature in the modification treatment of the principal surface 11 is preferably relatively high, and higher than the treatment temperature in the removal treatment of the layer 20. Note that the atmosphere gas may be switched so that N₂ gas is used first and H₂ gas is used next as the atmosphere gas. By terminating the treatment in the H₂ gas atmosphere, the principal surface 11 (the SiC constituting the principal surface 11) can be more preferably modified (cleaned).

In the modification treatment of the principal surface 11, the C component is desorbed from the Si-deficient region 12, and the Si-deficient region 12 is removed from the principal surface 11 (preferably, from the entire area of the principal surface 11). It is understood that C contained in the Si-deficient region 12 on the principal surface 11 reacts with the hydrogen-containing gas to generate hydrocarbon gas, whereby C is desorbed and Si-deficient region 12 is removed.

The modification treatment of the principal surface 11 is preferably performed under a condition under which the Si-deficient region 12 can be removed from the entire area of the principal surface 11. The conditions include, for example, a treatment temperature, a treatment time, and the like. For example, as described above, by setting the treatment temperature in the modification treatment of the principal surface 11 to a temperature higher than the treatment temperature in the removal treatment of the layer 20 and 900° C. or higher and 1200° C. or lower (preferably 1100° C. or higher and 1200° C. or lower), the Si-deficient region 12 can be removed from substantially the entire region (for example, a region of 90% or more) of the principal surface 11.

From the viewpoint of suitably removing the Si-deficient region 12, at least one gas selected from the group consisting of H₂ gas, NH₃ gas, N₂H₂ gas, N₂H₄ gas, and N₃H₈ gas may be used as the hydrogen-containing gas.

By removing the Si-deficient region 12 by the treatment of modifying the principal surface 11, a regenerated SiC substrate 10a having a clean principal surface 11 constituted from SiC is obtained. Thereafter, the temperature of the SiC substrate 10 (the regenerated SiC substrate 10a) is lowered to a predetermined temperature. In the present embodiment, as described above, the SiC substrate 10 is regenerated, that is, the regenerated SiC substrate 10a is manufactured.

The treatment of removing the layer 20 (FIG. 11A) and the treatment of modifying the principal surface 11 (FIG. 11B) are consecutively performed (without carrying out the SiC substrate 10 from the treatment vessel 210 and exposing it to the atmosphere midway in the treatment”) in the same treatment vessel 210. This allows improvement of the productivity of the regenerated SiC substrate 10a. In addition, contamination of the SiC substrate 10 due to atmospheric exposure or the like can be avoided. It is also preferable to consecutively perform the annealing treatment (FIG. 10B) as the pretreatment and the treatment of removing the layer 20 (FIG. 11A) in the same treatment vessel 210.

After a group III nitride was grown on a new SiC substrate 10, a test of regenerating the group III nitride by the method of the present embodiment was performed. The thickness of the new SiC substrate 10 was 0.4935 mm (analysis error±0.0003 mm), and the thickness of the regenerated SiC substrate 10a was 0.4936 mm (analysis error±0.0003 mm). According to the present embodiment, it has been found that the difference between the thickness of the SiC substrate 10 before regeneration and the thickness of the SiC substrate 10 after regeneration (regenerated SiC substrate 10a) can be suppressed within ±0.0003 mm (as one criterion), that is, the thickness of the regenerated SiC substrate 10a can be maintained substantially equal to the thickness of the SiC substrate 10 before regeneration.

In the regeneration method of the SiC substrate 10 according to the present embodiment, the SiC substrate 10 can be regenerated while suppressing a reduction in the thickness of the SiC substrate 10 due to the regeneration treatment as compared with the conventional regeneration method by polishing or the like, in this manner. Although the Si-deficient region 12 is formed and removed on the principal surface 11 of the SiC substrate 10 in the present embodiment, the fluctuation in the thickness of the SiC substrate 10 accompanying the removal of the Si-deficient region 12 is much smaller than the analysis error of the thickness measurement of the SiC substrate 10.

In addition, a test was performed in which the growth and removal of a group III nitride (specifically, a stack of high electron mobility transistor structures) on the SiC substrate 10 under the same conditions was repeated 18 times (that is, the regeneration was performed 18 times) by the method of the present embodiment starting from a new SiC substrate 10. The film thickness and Al composition of the AlGaN barrier layer grown on the new SiC substrate 10 were 21.3 nm and 0.277, respectively, and the film thickness of the GaN cap layer was 3.4 nm. The film thickness and the Al composition of the AlGaN barrier layer obtained by the 18-time regeneration growth were in the range of 21.1 nm to 21.6 nm and in the range of 0.271 to 0.276, respectively, and the film thickness of the GaN cap layer was in the range of 3.3 nm to 3.5 nm. In this manner, according to the method of the present embodiment, even when the regeneration is repeated, the growth of the group III nitride can be substantially performed in similar manner, and the regenerated SiC substrate 10a of constant quality can be repeatedly obtained. Since the thickness of the SiC substrate 10 does not substantially change even when the regeneration is repeated, it is not necessary to change (adjust) the growth condition of the group III nitride to be grown on the SiC substrate 10 in accordance with the decrease in the thickness of the SiC substrate as occurs in the conventional regeneration method by polishing or the like, and it is easy to repeatedly grow the group III nitride of constant quality.

As described above, the method of manufacturing a regenerated SiC substrate according to the present embodiment includes preparing a SiC substrate having a group III nitride adhered on a principal surface, removing the group III nitride from the principal surface by supplying a halogen-containing gas onto the SiC substrate, and supplying a hydrogen-containing gas to the SiC substrate from which the group III nitride has been removed to modify the principal surface.

In removing the group III nitride from the principal surface, a Si-deficient region is formed in the principal surface, and in modifying the principal surface, the Si-deficient region is removed from the principal surface. The Si-deficient region is preferably formed in the entire area of the principal surface and removed from the entire area of the principal surface.

Since the SiC substrate can be regenerated not by polishing or wet etching but by dry etching as in the present embodiment, productivity in manufacturing the regenerated SiC substrate can be increased.

However, according to intensive studies by the inventors of the present disclosure, it has been found that the quality of a crystal to be epitaxially grown on a regenerated SiC substrate may be deteriorated in some cases (for example, the number of defects appearing on the crystal surface increases) simply by performing dry etching to remove the group III nitride. When dry etching is performed using a halogen-containing gas, Si is desorbed from the principal surface of the SiC substrate exposed by removal of the group III nitride, and as a result, a “Si-deficient region” containing graphene or the like may be generated on the principal surface in some cases. This Si-deficient region is considered to be a factor that lowers the quality of crystals epitaxially grown on the principal surface of the regenerated SiC substrate.

On the other hand, according to intensive studies by the inventors of the present disclosure, it has been found that the state of the new principal surface (refreshed principal surface) obtained by forming and removing the Si-deficient region is improved in crystal quality and is suitable as a base surface for epitaxial growth as compared with the state of the principal surface not having undergone the treatment, that is, the state of the original principal surface which is considered to include the SiC crystal damaged in the processing steps at the time of manufacturing the substrate.

According to the embodiment of the present disclosure, in removing the group III nitride from the principal surface, the Si-deficient region is intentionally formed on the principal surface of the SiC substrate, and in the subsequently performed principal surface modifying, the Si-deficient region is removed from the principal surface, whereby a high-quality regenerated SiC substrate can be obtained.

The treatment apparatus 200 according to the present embodiment may also be a deposition apparatus, and a group III nitride growth treatment may be performed prior to the regeneration treatment of the SiC substrate 10. As illustrated in FIG. 10B, a deposit 270 containing a group III nitride may adhere to the inner wall of the treatment vessel 210 at the time of starting the regeneration treatment of the SiC substrate 10 due to the growth treatment. Although the deposit 270 may be adhered to the entire inner wall of the treatment vessel 210, the deposit 270 is illustrated in one granular shape for simplification of illustration.

In order to remove the deposit containing the group III nitride, that is, in order to clean the inside of the treatment vessel of the deposition apparatus, a cleaning treatment of supplying a halogen-containing gas into the treatment vessel is generally performed. As illustrated in FIG. 11A, the treatment of removing the layer 20 (group III nitride) from the principal surface 11 of the SiC substrate 10 in the present embodiment also functions as a cleaning treatment because the halogen-containing gas is supplied into the treatment vessel 210, and has an effect of removing the deposit 270 adhered to the inner wall of the treatment vessel 210.

Therefore, it can be said that removing the layer 20 (and modifying the principal surface 11) is performed concurrently with cleaning the inside of the treatment vessel 210. Note that the treatment conditions of the treatment of removing the layer 20 may not be optimal as the treatment conditions of the treatment of cleaning the inside of the treatment vessel 210. In order to further secure the effect of the cleaning treatment, removing the layer 20 (and modifying the principal surface 11) and cleaning the inside of the treatment vessel 210 (under treatment conditions suitable for cleaning, additionally, before or after removing the layer 20) may be consecutively performed.

By concurrently or consecutively performing removing the layer 20 (and modifying the principal surface 11) and cleaning the inside of the treatment vessel 210, the productivity thereof can be improved. In addition, the halogen-containing gas, the electric power, and the like can be effectively used, and the treatment cost thereof can be reduced.

In a deposition apparatus for growing a group III nitride, the inside of a treatment vessel is originally cleaned by dry etching using a halogen-containing gas. Therefore, the method of manufacturing the regenerated SiC substrate according to the present embodiment can be easily performed using the deposition apparatus, and the use of the deposition apparatus eliminates the need for another treatment apparatus for performing the regeneration treatment of the SiC substrate. Further, by using the deposition apparatus to carry out the method of manufacturing a regenerated SiC substrate according to the present embodiment, the effect of cleaning the inside of the treatment vessel of the deposition apparatus can also be obtained.

### Modification Example

The treatment of removing the layer 20 and the treatment of modifying the principal surface 11 may be alternately performed over a plurality of times. Specifically, for example, the period PL in which the period P2 (the treatment of removing the layer 20) and the period P3 (the treatment of modifying the principal surface 11) of FIG. 12 are combined as a pair may be repeated over a plurality of times.

Although a sufficient effect can be obtained by performing the treatment of removing the layer 20 and the treatment of modifying the principal surface 11 only once, the effect of the cleaning principal surface 11 of the SiC substrate 10 can be further enhanced by repeating these treatments. In addition, by such repetition, the effect of cleaning the inside of the treatment vessel 210 can be further enhanced.

### Other Modification Examples

In the above-described embodiments, an aspect in which the regeneration treatment of one SiC substrate 10 is performed is exemplified, but in the present modification example, an aspect in which the regeneration treatment of a plurality of SiC substrates 10 is simultaneously performed will be described. In preparing the SiC substrate, a plurality of SiC substrates 10 on which the layer 20 is deposited are prepared.

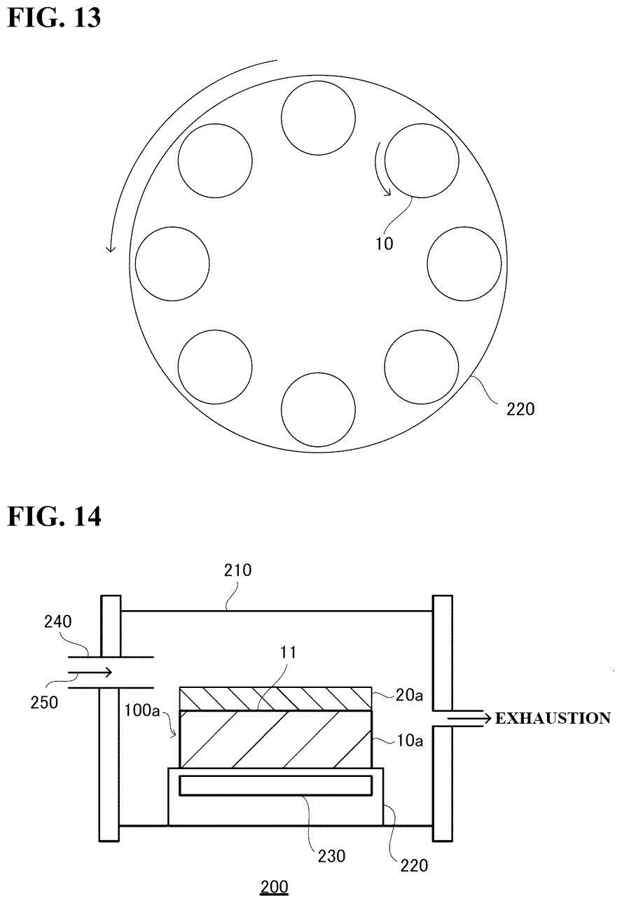

FIG. 13 is a schematic diagram illustrating a susceptor 220 on which a plurality of SiC substrates 10 are placed according to the present modification example. The susceptor 220 holds the plurality of SiC substrates 10 so as to revolve and rotate. While revolving and rotating each SiC substrate 10, a halogen-containing gas is simultaneously supplied onto each SiC substrate 10 to etch and remove the layer 20 of each SiC substrate 10, and a hydrogen-containing gas is simultaneously supplied onto each SiC substrate 10 after the etching and removal of the layer 20 to modify the principal surface 11 of each SiC substrate 10.

According to the present modification example, the regeneration treatment of the plurality of SiC substrates 10 can be efficiently performed. In addition, by performing etching removal of the layer 20 and modification of the principal surface 11 while revolving and rotating the plurality of SiC substrates 10, variations in the progress of etching and variations in the progress of modification of the principal surface between the SiC substrates 10 and in the plane of each SiC substrate 10 can be suppressed.

### Embodiment Applying Second Embodiment

A method of manufacturing a stack structure will be described as an embodiment to which the method of manufacturing a regenerated SiC substrate according to the above-described embodiment is applied. The method of manufacturing the stack structure according to the present embodiment includes growing a crystal on the modified principal surface of the SiC substrate (that is, the principal surface of the regenerated SiC substrate), in addition to the above-described steps of the method of manufacturing the regenerated SiC substrate. The crystal grown on the principal surface of the regenerated SiC substrate is preferably a group III nitride crystal.

FIG. 14 is a schematic view illustrating growing a new layer 20a (crystal) constituted from a group III nitride on the principal surface 11 of the regenerated SiC substrate 10a (on the modified principal surface 11 of the SiC substrate 10). Here, an aspect in which a deposition apparatus is used as the treatment apparatus 200 that performs the regeneration treatment of the SiC substrate 10, and the same treatment apparatus 200 is used to grow the layer 20a is exemplified.

For example, the treatment apparatus 200 is an MOVPE apparatus, and the layer 20a is grown on the principal surface 11 of the regenerated SiC substrate 10a by MOVPE. The treatment of growing the layer 20a may be consecutively performed in the same treatment vessel 210 as the regeneration treatment of the SiC substrate 10 (that is, the removal treatment of the layer 20 and the modification treatment of the principal surface 11). Thus, a stack structure 100a in which the layer 20a is stacked on the principal surface 11 of the regenerated SiC substrate 10a is manufactured.

The Si-deficient region 12 is removed from the principal surface 11 of the regenerated SiC substrate 10a, and the crystal quality of the layer 20a can be improved by performing growth on the principal surface 11. As a result, the performance and reliability of the semiconductor device manufactured using the stack structure 100a can be improved.

By consecutively performing the treatment of growing the layer 20a in the same treatment vessel 210 as the regeneration treatment of the SiC substrate 10 (that is, by performing the treatment subsequent to the regeneration treatment), productivity in manufacturing the stack structure 100a using the regenerated SiC substrate 10a can be improved. In addition, contamination of the regenerated SiC substrate 10a due to atmospheric exposure or the like can be avoided, and the performance and reliability of the semiconductor device manufactured using the stack structure 100a can be improved.

### Third Embodiment

A method of manufacturing a regenerated substrate according to a third embodiment of the present disclosure will be described. A method of manufacturing a regenerated substrate according to the present embodiment includes: preparing a substrate on which a layer constituted from a group III nitride is deposited on a principal surface thereof; and supplying a halogen-containing gas onto the substrate to remove the layer by etching. In etching and removing the layer, the substrate is irradiated with monitor light, and a change in reflectance of the monitor light is measured. The method of manufacturing the regenerated substrate of the third embodiment is similar to that of the second embodiment except that the irradiation of the monitor light and the measurement are performed.

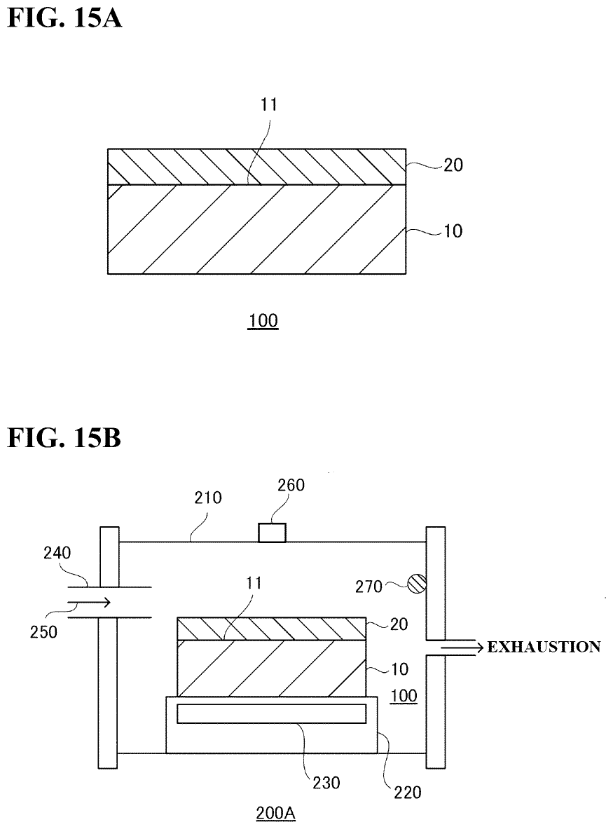

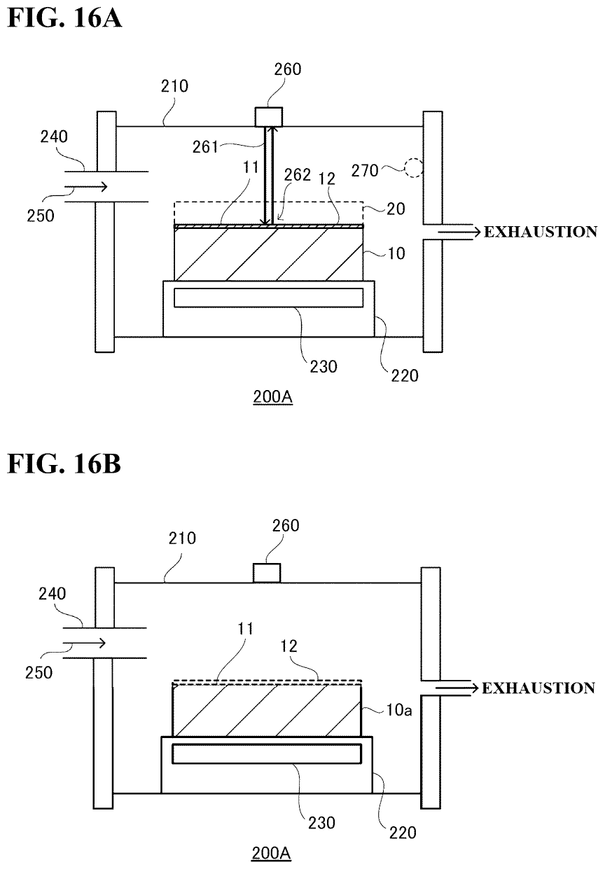

FIGS. 15A to 16B are schematic diagrams illustrating the flow of the regeneration treatment of the substrate 10. FIG. 12 is a timing chart (the similar timing chart as in the second embodiment) of the temperature and the gas supply in the regeneration treatment of the substrate 10.

FIG. 15A is a schematic view illustrating preparing a substrate 10 (stack structure 100) on which a layer 20 constituted from a group III nitride is deposited on a principal surface 11. The stack structure 100 in the third embodiment is similar to the stack structure 100 in the second embodiment. However, in the third embodiment, the substrate 10 to be regenerated is not limited to the SiC substrate.

The substrate 10 is constituted from a material different from the group III nitride and less easily etched by the halogen-containing gas than the group III nitride constituting the layer 20 when the layer 20 is etched and removed. The principal surface 11 is an upper surface of the substrate 10 and is a flat surface. Specifically, a silicon carbide (SiC) substrate, a diamond (C) substrate, or the like is used as the substrate 10. In the following description, an aspect in which a SiC substrate is used as the substrate 10 in similar manner as in the second embodiment will be described as an example.

FIG. 15B is a schematic diagram illustrating carrying the stack structure 100 into the treatment apparatus 200A and performing a pretreatment prior to a treatment of etching and removing the layer 20. As the treatment apparatus 200A in the third embodiment, an apparatus obtained by adding a reflected light monitor 260 to the treatment apparatus 200 in the second embodiment can be used.

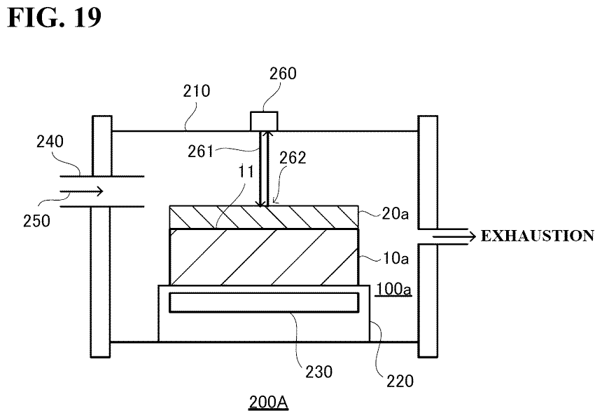

The treatment apparatus 200A according to the present embodiment is also a deposition apparatus, and includes a reflected light monitor 260 as an apparatus preferably provided with the deposition apparatus. The reflected light monitor 260 in the deposition apparatus (see FIG. 19) measures various physical properties of the growing group III nitride (layer 20a) by irradiating the substrate 10a on which the group III nitride is being grown with monitor light 261 and detecting the reflected light. The reflected light monitor 260 typically measures at least one of the growth rate and the film thickness of the growing group III nitride based on interference due to the thickness of the growing group III nitride. As the reflected light monitor 260, a known reflected light monitor provided in the deposition apparatus may be used.

As the pretreatment, a treatment similar to the pretreatment described in the second embodiment is performed (see a period P1 in FIG. 12). By the annealing treatment, the oxide film (natural oxide film or the like) formed on the surface of the layer 20 can be removed, and the removal of the group III nitride to be performed thereafter can proceed reliably and efficiently.

FIG. 16A is a schematic diagram illustrating supplying a halogen-containing gas onto the substrate 10 to etch and remove the layer 20. As the removal treatment, a treatment similar to the removal treatment of the layer 20 described in the second embodiment is performed (see a period P2 in FIG. 12). In the treatment of etching and removing the layer 20, the entire thickness of the layer 20 is removed to expose the entire area of the principal surface 11 of the substrate 10.

In the present embodiment, the reflected light monitor 260 is used to detect the end point of the treatment of etching and removing the layer 20. Specifically, in etching and removing the layer 20, the substrate 10 is irradiated with the monitor light 261, the change in the reflectance of the monitor light 261 is measured, and the end point of the treatment of etching and removing the layer 20 is detected based on the change in the reflectance of the monitor light 261. After the end point is detected, the supply of the halogen-containing gas onto the substrate 10 is stopped.

The monitor light 261 emitted to the substrate 10 is reflected by the surface of the layer 20 in a state where the layer 20 remains on the substrate 10, and is reflected by the principal surface 11 of the substrate 10 in a state where the layer 20 is removed from the substrate 10. More specifically, in a state where the layer 20 covers the entire area of the principal surface 11 of the substrate 10 (the entire surface of the region corresponding to the measurement position 262) according to the progress of the etching removal process of the layer 20, the monitor light 261 is reflected by only the surface of the layer 20, and in a state where a region of the principal surface 11 of the substrate 10 is exposed and a region of the layer 20 remains (in the plane, the layer 20 remaining in an island shape and the exposed principal surface 11 of the substrate 10 are mixed), the monitor light 261 is reflected by both the surface of the layer 20 and the principal surface 11 of the substrate 10, and in a state where the layer 20 is completely removed from the substrate 10 (a state where the principal surface 11 of the substrate 10 is completely exposed), the monitor light 261 is reflected only by the principal surface 11 of the substrate 10.

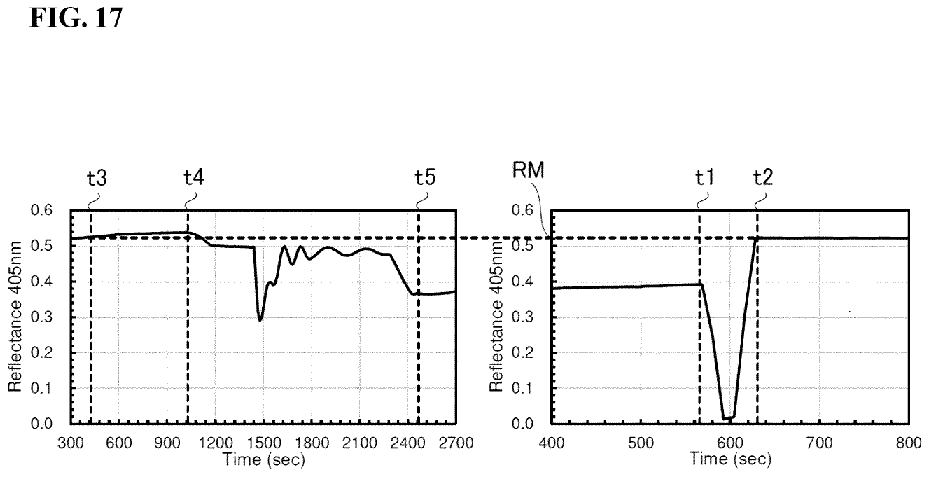

FIG. 17 is a graph illustrating an example of a change in reflectance of the monitor light 261. The graph on the right side of FIG. 17 is a graph of the change in reflectance of the monitor light 261 in the experimental example in which the layer 20 is removed by etching. In this experimental example, light having a wavelength of 405 nm is used as the monitor light 261. The reflectance measured in the etching removal process of the layer 20 is understood to reflect the surface roughness of the layer 20 (or the principal surface 11 of the substrate 10), and the surface of the layer 20 (or the principal surface 11 of the substrate 10) is evaluated to be flatter as the reflectance of the monitor light 261 is higher, and rougher as the reflectance is lower. Hereinafter, the reflectance of the monitor light 261 is also simply referred to as a reflectance.

Time t1 is a start time of introduction of the halogen-containing gas into the treatment vessel 210. The surface of the layer 20 at time t1, i.e., before the start of etching, is a relatively flat surface formed by epitaxial growth, and exhibits flatness of about 0.4 (0.3 or more) as the reflectance in the measurement of the present example.

After time t1, the layer 20 is etched by the halogen-containing gas, so that the surface of the layer 20 becomes rough, and the reflectance decreases accordingly. The surface of the layer 20 after the start of etching reaches a roughness of 0.2 or less, and further reaches a roughness of 0.1 or less as the reflectance in the measurement of the present example.

The reflectance of the monitor light 261 changes to the rise after reaching a minimum value (about 0.02). It is understood that the reason why the reflectance changes to the rise is that the etching of the layer 20 proceeds, the principal surface 11 of the substrate 10 starts to be exposed, and the exposed area of the principal surface 11 increases, so that the flatness of the surface reflecting the monitor light 261 increases.

The reflectance that has changed to the rise reaches the maximum value RM at time t2. This is understood to be because, at time t2, the removal of the layer 20 is completed and the principal surface 11 of the substrate 10 is completely exposed. After time t2, it is determined that the reflectance reaches the maximum value when the reflectance becomes constant (for example, the change width of the reflectance is ±0.01 or less). In this way, it is detected that the layer 20 has been completely removed, that is, that the treatment of etching and removing the layer 20 has reached the end point.

The principal surface 11 of the substrate 10 is provided as a flatter surface as compared with the surface of the layer 20 at the time when the surface becomes the roughest as the layer 20 is etched, and the maximum value RM of the reflectance can be said to be a value corresponding to the flatness of the principal surface 11. The principal surface 11 of the substrate 10 exhibits flatness of more than 0.5 (0.3 or more, 0.4 or more) as the reflectance in the measurement of the present example.

The graph on the left side of FIG. 17 is a graph of a change in reflectance of the monitor light 261 in an experimental example in which a group III nitride is grown on a growth base substrate similar to the substrate 10. Until time t4, the temperature of the growth base substrate is raised to the growth treatment temperature of the group III nitride, and from time t4 to time t5, the group III nitride is grown.

Time t3 indicates a time point when the temperature of the growth base substrate before the growth of the group III nitride becomes equal to the etching removal treatment temperature of the layer 20. It can be seen that the reflectance RM at time t2 in the graph on the right side (etching removal process) is equal to the reflectance at time t3 in the graph on the left side (group III nitride growth). That is, it is understood that the reflectance RM is equal to the reflectance of the principal surface 11 of the substrate 10 at the etching removal treatment temperature of the layer 20, and that the layer 20 is completely removed and the entire area of the principal surface 11 of the substrate 10 is exposed at the time t2.

As described above, in the present embodiment, the end point of the treatment of etching and removing the layer 20 is detected based on the behavior in which the reflectance of the monitor light 261 once decreases as the layer 20 is etched and removed and then increases. As a result, as compared with a behavior in which the reflectance monotonously changes (monotonously increases), for example, from the time t1 to the time t2, the change in reflectance becomes remarkable, and the determination of the end point detection based on the change in reflectance can be performed more clearly.

In order to temporarily reduce the reflectance in accordance with the etching, a treatment of etching and removing the layer 20 is performed under a condition under which the surface of the layer 20 becomes increasingly rough in accordance with the etching and removal of the layer 20. In order to roughen the surface of the layer 20, for example, the halogen-containing gas concentration in the treatment gas in the etching removal treatment of the layer 20 is preferably 0.01% or more (preferably 0.1% or more, and more preferably 1.0% or more). The upper limit of the halogen-containing gas concentration is, for example, 10% or less (preferably 5% or less, more preferably 3% or less). In order to roughen the surface of the layer 20, the above-described pretreatment (annealing of the substrate 10 in a reducing atmosphere) is preferably performed, for example, before etching and removing the layer 20 using a halogen-containing gas.

In the present example in which the substrate 10 is constituted from SiC, since the principal surface 11 is exposed to the halogen-containing gas to form the Si-deficient region 12 in the principal surface 11, the exposed principal surface 11 may be in a state in which the Si-deficient region 12 is formed. According to the insights obtained by the inventors of the present disclosure, the flatness of the principal surface 11 does not change particularly due to the formation of the Si-deficient region 12.

At the time t2 when the reflectance reaches the maximum value RM, that is, at the time when the entire area of the principal surface 11 is exposed, the reaction in which the Si-deficient region 12 is formed is considered to be substantially completed, but from the viewpoint of further ensuring the reaction in which the Si-deficient region 12 is formed, the supply of the halogen-containing gas may not be terminated immediately after the time t2, and may be continued for a certain period of time (for example, about 360 seconds) after the time t2.

FIG. 16B is a schematic diagram illustrating supplying a hydrogen-containing gas onto the substrate 10 from which the layer 20 (group III nitride) has been removed to modify the principal surface 11. As the modification treatment, a treatment similar to the modification treatment of the principal surface 11 described in the second embodiment is performed (see a period P3 in FIG. 12). By removing the Si-deficient region 12 by the treatment of modifying the principal surface 11, a regenerated substrate 10a having a clean principal surface 11 constituted from SiC is obtained. Thereafter, the temperature of the regenerated substrate 10a is lowered to a predetermined temperature. In the present embodiment, as described above, the substrate 10 is regenerated, that is, the regenerated substrate 10a is manufactured.

Also in the method of manufacturing the regenerated substrate according to the third embodiment, as in the method of manufacturing the regenerated substrate according to the second embodiment, contamination of the regenerated substrate due to atmospheric exposure or the like can be avoided, and a good-quality regenerated substrate can be repeatedly obtained. In addition, a high-quality group III nitride can be repeatedly grown using the regenerated substrate.

As described above, the method of manufacturing a regenerated substrate according to the present embodiment includes preparing a substrate on which a layer constituted from a group III nitride is deposited on a principal surface, and supplying a halogen-containing gas onto the substrate to etch and remove the layer. In etching and removing the layer, the substrate is irradiated with monitor light, and a change in reflectance of the monitor light is measured.

By measuring the reflectance of the monitor light with which the substrate is irradiated during the progress of the etching removal treatment of the layer constituted from the group III nitride, the progress of the etching removal treatment (e.g., the etching end point) can be grasped in real time in situ.

In the method of manufacturing a regenerated substrate according to the present embodiment, in etching and removing the layer, the end point of the treatment of etching and removing the layer is detected based on the change in the reflectance of the monitor light. After the end point is detected, the supply of the halogen-containing gas onto the substrate is stopped.

Since it can be confirmed that the group III nitride is removed based on the change in the reflectance of the monitor light with which the substrate is irradiated, the end point of the etching can be more reliably detected. Since the halogen-containing gas supply is prevented from being stopped during the removal of the group III nitride, the group III nitride can be reliably removed.

The method of manufacturing a regenerated substrate according to the present embodiment may be performed by using a deposition apparatus capable of growing a group III nitride as a treatment apparatus for etching and removing a layer constituted from a group III nitride. Further, the measurement of the change in reflectance during the etching removal treatment of the layer may be performed by using a reflected light monitor included in the deposition apparatus. This eliminates the need to separately prepare another device for performing the substrate regeneration treatment.

The reflected light monitor in the deposition apparatus is used as an apparatus for measuring at least one of the film thickness and the growth rate of the growing group III nitride based on interference caused by the thickness of the growing group III nitride. Unlike the mode of usage (measurement of the film thickness or the growth rate) in the case of being used in the growth of the group III nitride, the mode of usage of the reflected light monitor in the case of being used in the etching removal treatment of the group III nitride is a mode of usage in which the reflectance of the monitor light is measured as a physical property value corresponding to the surface roughness of the principal surface of the substrate and the surface of the layer constituted from the group III nitride.

The technique of measuring the change in reflectance of the monitor light as described above can be preferably used even in the exemplified case of performing substrate regeneration other than the SiC substrate. When the SiC substrate is regenerated, various effects related to the regeneration of the SiC substrate as described in the second embodiment can be obtained.

### Modification Example

Next, a modification example of the above-described embodiment will be described. In the present modification example, a mode in which the regeneration treatment of the plurality of substrates 10 is performed simultaneously, in particular, a mode in which the reflectance change measurement when the etching removal treatment of the layer 20 is performed is performed on the plurality of substrates 10 will be described. In preparing the substrate, a plurality of substrates 10 on which a layer 20 is deposited are prepared.

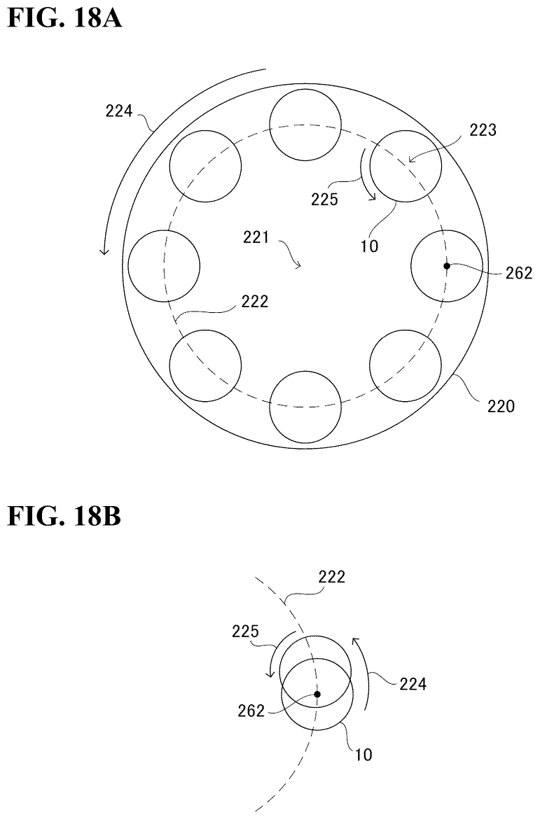

FIG. 18A is a schematic diagram illustrating the susceptor 220 on which the plurality of substrates 10 are placed and the measurement position 262 of the monitor light 261 according to the present modification example, and FIG. 18B is a schematic diagram illustrating the vicinities of the measurement position 262.

The susceptor 220 of the present modification example holds the plurality of substrates 10 so as to revolve and rotate. Specifically, the plurality of substrates 10 are arranged so that the centers thereof are aligned on a circumference (orbit of revolution) 222 centered on a revolution rotation center 221 (so as to be aligned in the circumferential direction of revolution). The center of each substrate 10 (having a circular shape) is defined as a rotation center 223 of rotation. Each substrate 10 revolves along with the rotation of the susceptor 220 (moves in a revolving direction 224), and rotates while revolving (moves in a rotation direction 225). The measurement position 262 of the monitor light 261 is disposed at a predetermined point on the circumference 222 (that is, on a circumference centered on the revolution rotation center 221 and having a radius from the revolution rotation center 221 to the rotation center 223).

In the present modification example, the halogen-containing gas is simultaneously supplied onto each substrate 10 while each substrate 10 revolves around the rotation center 221 and rotates around the rotation center 223, and the layer 20 of each substrate 10 is etched and removed. Then, at the measurement position 262, each time the substrate 10 passes through the measurement position 262 along with revolution, the monitor light 261 is emitted to each substrate 10, thereby measuring a change in the reflectance of the monitor light 261 with respect to each substrate 10.

By performing etching removal of the layer 20 while revolving and rotating the plurality of substrates 10, variations in etching progress between the substrates 10 and in the plane of each substrate 10 can be suppressed. Further, the present modification example has the following advantages by performing the measurement of the reflectance at the measurement position 262 while performing the etching removal of the layer 20 by revolving and rotating the plurality of substrates 10.

A single period in which one substrate 10 passes through the measurement position 262 once as the substrate revolves is referred to as a (one-time) measurement period. Hereinafter, the radial direction and the circumferential direction with respect to the substrate 10 are also simply referred to as a radial direction and a circumferential direction, respectively. The relative point of the measurement position 262 on the substrate 10 in plan view is also hereinafter simply referred to as a measurement position 262 on the substrate 10. During the measurement period, the measurement position 262 on the substrate 10 moves substantially in the radial direction along with revolution and also moves in the circumferential direction along with rotation (see FIG. 18B).

Therefore, by controlling the revolution speed and the rotation speed, the measurement position 262 on the substrate 10 can be controlled in the radial direction and the circumferential direction, and the measurement position 262 on the substrate 10 can be controlled to be disposed at a predetermined point in the plane of the substrate 10.

In the present modification example, the reflectance measurement may be performed over a plurality of times (not limited to being performed only once) during one measurement period. That is, the reflectance may be measured at a plurality of positions on the substrate 10 during one measurement period. Accordingly, for example, since the in-plane distribution (at least one of the radial distribution and the circumferential distribution) of the reflectance in the substrate 10 can be obtained, the etching removal of the layer 20 can be performed while confirming the uniformity of the etching progress in the in-plane. This also allows, for instance, obtaining insights into changes in reflectance during one measurement period.

In the present modification example, the change in the reflectance of the monitor light 261 is measured for each substrate 10, and the end point of the treatment of etching and removing the layer 20 can be detected based on the change in the reflectance of the monitor light 261. Preferably, the supply of the halogen-containing gas onto the substrates 10 is stopped after the end point of the treatment of etching and removing the layer 20 with respect to all the substrates 10 is detected. This ensures completion of etching removal of the layer 20 for all of the plurality of substrates 10.

### Embodiment Applying Third Embodiment

As an embodiment to which the method of manufacturing a regenerated substrate according to the above-described embodiment is applied, a method of manufacturing a stack structure will be described. The method of manufacturing a stack structure according to the present embodiment includes, in addition to the steps of the above-described method of manufacturing a regenerated substrate, growing a crystal on the principal surface (that is, the principal surface of the regenerated substrate) from which the layer constituted from the group III nitride has been etched and removed. The crystal grown on the principal surface of the regenerated substrate is preferably a group III nitride crystal.

FIG. 19 is a schematic view illustrating growing a new layer 20a (crystal) constituted from a group III nitride on the principal surface 11 of the regenerated substrate 10a (on the principal surface 11 from which the layer 20 has been etched and removed). Here, a mode in which a deposition apparatus is used as the treatment apparatus 200A that performs the regeneration treatment of the substrate 10 and the same treatment apparatus 200A is used to grow the layer 20a is exemplified.

For example, the treatment apparatus 200A is an MOVPE apparatus, and the layer 20a is grown on the principal surface 11 of the regenerated substrate 10a by MOVPE. The treatment of growing the layer 20a may be consecutively performed in the same treatment vessel 210 as the regeneration treatment (that is, the etching removal treatment of the layer 20 and the modification treatment of the principal surface 11) of the substrate 10. In this manner, the stack structure 100a in which the layer 20a is stacked on the principal surface 11 of the regenerated substrate 10a is manufactured.

According to the present embodiment, the stack structure 100a that can be used for a semiconductor device can be manufactured using the regenerated substrate 10a. Also in the present disclosure mode, as described above, by performing the reflectance measurement in the etching removal treatment of the layer 20 when the regenerated substrate 10a is obtained, the progress status of the etching removal process (e.g., the etching end point) can be grasped in real time in situ.

By consecutively performing the treatment of growing the layer 20a in the same treatment vessel 210 as the regeneration treatment of the substrate 10 (that is, by performing the treatment subsequent to the regeneration treatment), productivity in manufacturing the stack structure 100a using the regenerated substrate 10a can be improved. In addition, contamination of the regenerated substrate 10a due to atmospheric exposure or the like can be avoided, and the performance and reliability of the semiconductor device manufactured using the stack structure 100a can be improved.

### Preferred Modes of the Present Disclosure

Hereinafter, preferred modes of the present disclosure will be additionally described.

(Supplementary description 1)

A group III nitride stack comprising
a SiC substrate and,
a stack structure provided on the substrate and formed by epitaxially growing a group III nitride crystal, wherein
the stack structure has an average density of surface defects of 10.0 defects/cm² or less in an internal region of a surface of the stack structure, the surface defects each having a size of 0.165 μm or more and 2.0 μm or less, the internal region being a region excluding a width of 5 mm from an outer edge of the surface of the stack structure, and
when the internal region is segmented into a plurality of 10 mm-square region segments and a density of the surface defects in each region segment is measured, the maximum value of the density is 50.0 defects/cm² or less.

### (Supplementary Description 2)

The group III nitride stack according to the supplementary description 1, wherein
the average defect density is 7.0 defects/cm² or less, and
the maximum value of the defect density is 30.0 defects/cm² or less.

### (Supplementary Description 3)

The group III nitride stack according to the supplementary description 1, wherein
the average defect density is 5.0 defects/cm² or less, and
the maximum value of the defect density is 20.0 defects/cm² or less.

### (Supplementary Description 4)

The group III nitride stack according to any one of the supplementary descriptions 1 to 3, wherein
the stack structure comprises
a nucleation layer provided on the SiC substrate and containing aluminum nitride, and
a channel layer provided on the nucleation layer and expressed by a composition formula of InₓAl_{y}Ga_{(1-x-y)}N (0≤x≤1, 0≤y≤1, x+y≤1),
the surface of the stack structure being the channel layer.

### (Supplementary Description 5)

The group III nitride stack according to any one of the supplementary descriptions 1 to 3, wherein
the stack structure comprises
a nucleation layer provided on the SiC substrate and containing aluminum nitride,
a channel layer provided on the nucleation layer and containing a group III nitride expressed by a composition formula of InₓAl_{y}Ga_{(1-x-y)}N (0≤x≤1, 0≤y≤1, x+y≤1), and
a functional layer provided on the channel layer and containing a group III nitride expressed by a composition formula of InₓAl_{y}Ga_{(1-x-y)}N (0≤x≤1, 0≤y≤1, x+y≤1),
the surface of the stack structure being the functional layer.

### (Supplementary Description 6)

The group III nitride stack according to any one of the supplementary descriptions 1 to 5,
the stack having a diameter of 4 inches or more.

### (Supplementary Description 7)

A group III nitride stack comprising
a SiC substrate and
a stack structure provided on the substrate and formed by epitaxially growing a group III nitride crystal, wherein
the stack structure has relative yellow intensities of 1.30 or less, each of the relative yellow intensities being a ratio of yellow emission intensity to band edge emission intensity of photoluminescence at a surface center of the stack structure, and
a fluctuation rate (Xₘₐₓ−Xₘᵢₙ)/X_{avg} of the relative yellow intensities is 20% or less, wherein in the fluctuation rate, Xₘₐₓ, Xₘᵢₙ, and X_{avg} respectively denote the maximum value, minimum value, and average of the relative yellow intensities taken at three or more points in an internal region of the surface of the stack structure, the internal region excluding a width of 5 mm from the outer edge of the surface, the three or more points being freely selected along a central line of the surface, the three or more points including the center of the surface and two or more points spaced apart from the center.

### (Supplementary Description 8)

The group III nitride stack according to the supplementary description 7, wherein
the relative yellow intensity at the surface center is 1.25 or less, and
the fluctuation rate of the relative yellow intensities is 15% or less.

### (Supplementary Description 9)

The group III nitride stack according to supplementary description 7, wherein
the relative yellow intensity at the surface center is 1.20 or less, and
the fluctuation rate of the relative yellow intensities is 10% or less.

(Supplementary Description 10)

The group III nitride stack according to any one of the supplementary descriptions 7 to 9, wherein
the stack structure comprises
a nucleation layer provided on the SiC substrate, and
a channel layer provided on the nucleation layer and expressed by a composition formula of InₓAl_{y}GaN (0≤x≤1, 0≤y≤1, x+y≤1),
the surface of the stack structure being the channel layer.

### (Supplementary Description 11)

The group III nitride stack according to any one of the supplementary descriptions 7 to 9, wherein
the stack structure comprises
a nucleation layer provided on the SiC substrate,
a channel layer provided on the nucleation layer and expressed by a composition formula of InₓAl_{y}GaN (0≤x≤1, 0≤y≤1, x+y≤1), and
a functional layer provided on the channel layer and containing a group III nitride having a wider band gap than gallium nitride,
the surface of the stack structure being the functional layer.

### (Supplementary Description 12)

The group III nitride stack according to any one of the supplementary descriptions 7 to 11,
the stack having a diameter of 4 inches or more.

### (Supplementary Description 13)

A method of manufacturing a group III nitride stack, the method comprising
(a) preparing a SiC substrate,
(b) supplying a halogen-containing gas onto the SiC substrate to desorb Si from a principal surface of the SiC substrate and form a Si-deficient region in a surface layer of the principal surface,
(c) supplying a hydrogen-containing gas onto the SiC substrate having the Si-deficient region to remove the Si-deficient region, and performing surface treatment of the principal surface, and
(d) growing a group III nitride crystal on the principal surface having undergone the treatment.

### (Supplementary Description 14)

The method of manufacturing a group III nitride stack according to the supplementary description 13, wherein
said (c) is performed under a condition under which the Si-deficient region is removed from the entire area of the principal surface of the SiC substrate.

### (Supplementary Description 15)

The method of manufacturing a group III nitride stack according to the supplementary description 13 or 14, wherein
said (b) is performed under a condition under which the Si-deficient region is formed over the entire area of the principal surface of the SiC substrate.

### (Supplementary Description 16)

The method of manufacturing a group III nitride stack according to any one of the supplementary descriptions 13 to 15, wherein
said (c) is performed at a higher temperature than said (b).

### (Supplementary Description 17)

The method of manufacturing a group III nitride stack according to any one of the supplementary descriptions 13 to 16, wherein
said (c) is performed at a temperature of 1050° C. to 1250° C.

### (Supplementary Description 18)

The method of manufacturing a group III nitride stack according to any one of the supplementary descriptions 13 to 17, wherein
said (b) is performed at a temperature of 850° C. to 1150° C.

### (Supplementary Description 19)

The method of manufacturing a group III nitride stack according to any one of the supplementary descriptions 13 to 18, wherein
said (b), said (c) and, said (d) are consecutively performed in the same treatment vessel.

### (Supplementary Description 20)

The method of manufacturing a group III nitride stack according to any one of the supplementary descriptions 13 to 19, wherein
said (b) and said (c) are alternately performed over a plurality of times.

### (Supplementary Description 21)

The method of manufacturing a group III nitride stack according to any one of the supplementary descriptions 13 to 20,
the method comprising annealing the SiC substrate in a reducing atmosphere before said (b).

### (Supplementary Description 22)

The method of manufacturing a group III nitride stack according to any one of the supplementary descriptions 13 to 21, wherein
in said (d), a substance represented by a composition formula of InₓAl_{y}Ga_{(1-x-y)}N (0≤x≤1, 0≤y≤1, x+y≤1) is grown as the group III nitride crystal.

### (Supplementary Description 23)

A method of manufacturing a regenerated SiC substrate, comprising
(a) preparing a SiC substrate having a group III nitride having adhered on a principal surface thereof,
(b) removing the group III nitride from the principal surface by supplying a halogen-containing gas onto the SiC substrate, and
(c) supplying a hydrogen-containing gas onto the SiC substrate from which the group III nitride has been removed to modify the principal surface.

### (Supplementary Description 24)

The method of manufacturing a regenerated SiC substrate according to the supplementary description 23, wherein
in said (b), a Si-deficient region is formed in the principal surface, and
in said (c), the Si-deficient region is removed from the principal surface.

### (Supplementary Description 25)

The method of manufacturing a regenerated SiC substrate according to the supplementary description 24, wherein
said (b) is performed under a condition under which the Si-deficient region can be formed over the entire area of the principal surface.

### (Supplementary Description 26)

The method of manufacturing a regenerated SiC substrate according to the supplementary description 24, wherein
said (c) is performed under a condition under which the Si-deficient region can be removed from the entire area of the principal surface.

### (Supplementary Description 27)

The method of manufacturing a regenerated SiC substrate according to the supplementary description 26, wherein
said (c) is performed under a temperature condition higher than that of said (b).

### (Supplementary Description 28)

The method of manufacturing a regenerated SiC substrate according to the supplementary description 23, wherein
in said (b), at least one gas selected from the group consisting of F₂ gas, Cl₂ gas, Br₂ gas, I₂ gas, NF₃ gas, ClF₃ gas, HF gas, HCl gas, HBr gas, and HI gas is used as the halogen-containing gas.

### (Supplementary Description 29)

The method of manufacturing a regenerated SiC substrate according to the supplementary description 23, wherein
in said (c), at least one gas selected from the group consisting of H₂ gas, NH₃ gas, N₂H₂ gas, N₂H₄ gas, and N₃H₈ gas is used as the hydrogen-containing gas.

### (Supplementary Description 30)

The method of manufacturing a regenerated SiC substrate according to the supplementary description 23, wherein
the group III nitride includes a substance represented by a composition formula of InₓAl_{y}Ga_{(1-x-y)}N (0≤x≤1, 0≤y≤1, x+y≤1).

### (Supplementary Description 31)

The method of manufacturing a regenerated SiC substrate according to the supplementary description 23, wherein
said (b) and said (c) are consecutively performed in the same treatment vessel.

### (Supplementary Description 32)

The method of manufacturing a regenerated SiC substrate according to the supplementary description 23, wherein
said (b) and said (c), as well as supplying the halogen-containing gas into the treatment vessel to clean the inside of the treatment vessel, are performed concurrently or consecutively.

### (Supplementary Description 33)

The method of manufacturing a regenerated SiC substrate according to the supplementary description 23, wherein
said (b) and said (c) are alternately performed over a plurality of times.

### (Supplementary Description 34)

The method of manufacturing a regenerated SiC substrate according to the supplementary description 23, the method comprising
annealing the SiC substrate in a reducing atmosphere before said (b).

### (Supplementary Description 35)

The method of manufacturing a regenerated SiC substrate according to the supplementary description 23, wherein
said (b) and said (c) are performed in a cold wall type treatment vessel.

### (Supplementary Description 36)

The method of manufacturing a regenerated SiC substrate according to the supplementary description 23, wherein
the difference between the thickness of the SiC substrate prepared in said (a) and the thickness of the SiC substrate after said (c) is within ±0.0003 mm.

### (Supplementary Description 37)

The method of manufacturing a regenerated SiC substrate according to the supplementary description 23, wherein
in said (a), a plurality of SiC substrates each having a group III nitride having adhered on a principal surface thereof are prepared,
in said (b), a halogen-containing gas is simultaneously supplied onto the plurality of SiC substrates to remove the group III nitride from the principal surface of each SiC substrate, and
in said (c), a hydrogen-containing gas is simultaneously supplied onto each of the SiC substrates from which the group III nitride has been removed to modify the principal surface of each of the SiC substrates.

### (Supplementary Description 38)

A method of manufacturing a stack structure comprising
(a) preparing a SiC substrate having a group III nitride having adhered on a principal surface thereof,
(b) removing the group III nitride from the principal surface by supplying a halogen-containing gas onto the SiC substrate,
(c) supplying a hydrogen-containing gas onto the SiC substrate from which the group III nitride has been removed to modify the principal surface, and
(d) growing a crystal on the modified principal surface.

### (Supplementary Description 39)

The method of manufacturing a stack structure according to the supplementary description 38, wherein
said (b), said (c), and said (d) are consecutively performed in the same treatment vessel.

### (Supplementary Description 40)

A method of manufacturing a regenerated substrate, comprising
(a) preparing a substrate on which a layer constituted from a group III nitride is deposited on a principal surface thereof, and
(b) supplying a halogen-containing gas onto the substrate to etch and remove the layer, wherein
in said (b), the substrate is irradiated with monitor light and a change in reflectance of the monitor light is measured.

### (Supplementary Description 41)

The method of manufacturing a regenerated substrate according to the supplementary description 40, wherein
in said (b), an end point of a treatment of etching and removing the layer is detected based on a change in reflectance of the monitor light.

### (Supplementary Description 42)

The method of manufacturing a regenerated substrate according to the supplementary description 41, wherein
in said (b), after the end point is detected, the supply of the halogen-containing gas onto the substrate is stopped.

### (Supplementary Description 43)

The method of manufacturing a regenerated substrate according to the supplementary description 41, wherein
in said (b), an end point of a treatment of etching and removing the layer is detected based on a behavior in which the reflectance of the monitor light once decreases and then increases as the layer is etched and removed.

### (Supplementary Description 44)

The method of manufacturing a regenerated substrate according to the supplementary description 41, wherein
in said (b), an end point of a treatment of etching and removing the layer is detected based on a behavior in which the reflectance of the monitor light once decreases as the layer is etched and removed and then increases, and then a constant value is maintained after the reflectance reaches a predetermined reflectance.

### (Supplementary Description 45)

The method of manufacturing a regenerated substrate according to the supplementary description 44, wherein
in said (b), a treatment of etching and removing the layer under heating conditions is performed, and
the predetermined reflectance is a reflectance of the principal surface at a treatment temperature of the treatment of etching and removing the layer.

### (Supplementary Description 46)

The method of manufacturing a regenerated substrate according to the supplementary description 40, wherein
in said (b), a treatment of etching and removing the layer is performed under a condition under which the surface roughness of the surface of the layer becomes increasingly rough as the layer is etched and removed.

Note that the surface of the layer is evaluated to be flatter as the reflectance of the monitor light is higher, and rougher as the reflectance of the monitor light is lower. For example, when the surface roughness of the surface of the layer is expressed as a reflectance when light having a wavelength of 405 nm is used as the monitor light, the surface roughness before the start of etching of the layer is preferably a reflectance of 0.3 or more, and the surface roughness preferably reaches a reflectance of 0.2 or less, and more preferably a reflectance of 0.1 or less, along with the etching of the layer.

### (Supplementary Description 47)

The method of manufacturing a regenerated substrate according to the supplementary description 46, wherein
in said (b), the halogen-containing gas concentration in the treatment gas is 0.01% or more (preferably 0.1% or more, more preferably 1.0% or more).

Note that the halogen-containing gas concentration is, for example, 10% or less (preferably 5% or less, more preferably 3% or less).

### (Supplementary Description 48)

The method of manufacturing a regenerated substrate according to the supplementary description 46, wherein
the method comprises annealing the substrate in a reducing atmosphere before said (b).

### (Supplementary Description 49)

The method of manufacturing a regenerated substrate according to the supplementary description 46, wherein
the substrate is constituted from a material different from the group III nitride and less easily etched by the halogen-containing gas than the group III nitride, and
the principal surface is flatter than the surface of the layer at the time when same becomes roughest in accordance with the etching and removing of the layer.

Note that the principal surface of the substrate is evaluated to be flatter as the reflectance of the monitor light is higher, and rougher as the reflectance of the monitor light is lower. For example, the surface roughness of the principal surface is preferably a reflectance of 0.3 or more, and more preferably a reflectance of 0.4 or more, when expressed as a reflectance when light having a wavelength of 405 nm is used as the monitor light.

### (Supplementary Description 50)

The method of manufacturing a regenerated substrate according to the supplementary description 40, wherein
in said (b), a treatment of etching and removing the layer is performed in a treatment vessel of a deposition apparatus that can grow a group III nitride,
the deposition apparatus includes a reflected light monitor configured to measure at least one of a film thickness and a growth rate of a growing group III nitride based on interference due to the thickness of the growing group III nitride, and
in said (b), the reflectance of the monitor light is measured as a physical property value corresponding to the surface roughness of the surface of the layer and the principal surface of the substrate by using the reflected light monitor.

### (Supplementary Description 51)

The method of manufacturing a regenerated substrate according to the supplementary description 40, wherein
in said (b),
the halogen-containing gas is supplied onto the substrate while allowing the substrate to revolve about a first rotation center and rotating the substrate about a second rotation center, which is the center of the substrate, to etch and remove the layer, and
at a measurement position disposed on a circumference having a radius from the first rotation center to the second rotation center with the first rotation center as a center, each time the substrate passes through the measurement position as the substrate revolves, the monitor light is emitted to the substrate to measure a change in reflectance of the monitor light with respect to the substrate.

### (Supplementary Description 52)

The method of manufacturing a regenerated substrate according to the supplementary description 51, wherein
in said (b),
the reflectance is measured at a plurality of positions on the substrate during a single period in which the substrate passes through the measurement position once as the substrate revolves.

### (Supplementary Description 53)

The method of manufacturing a regenerated substrate according to the supplementary description 51, wherein
in said (a),
another substrate on which another layer constituted from a group III nitride is deposited on the principal surface is prepared,
in said (b),
the center of the substrate and the center of the other substrate are arranged side by side in a circumferential direction of revolution,
the halogen-containing gas is supplied onto the other substrate while allowing the other substrate to revolve around the first rotation center and rotating the other substrate around a third rotation center, which is the center of the other substrate, to etch and remove the other layer, and
at the measurement position, each time the other substrate passes through the measurement position as the other substrate revolves, the other substrate is irradiated with the monitor light to measure a change in reflectance of the monitor light with respect to the other substrate.

### (Supplementary Description 54)

The method of manufacturing a regenerated substrate according to the supplementary description 53, wherein
in said (b),
after detecting an end point of a treatment of etching and removing the layer in the substrate and an end point of a treatment of etching and removing the other layer in the other substrate based on a change in the reflectance of the monitor light,
the supply of the halogen-containing gas onto the substrate and the other substrate is stopped.

### (Supplementary Description 55)

A method of manufacturing a stack structure comprising
(a) preparing a substrate on which a layer constituted from a group III nitride is deposited on a principal surface thereof,
(b) supplying a halogen-containing gas onto the substrate to etch and remove the layer, and
(c) growing a crystal on the principal surface from which the layer has been etched and removed, wherein
in said (b), the substrate is irradiated with monitor light and a change in reflectance of the monitor light is measured.

### (Supplementary Description 56)

The method of manufacturing a stack structure according to the supplementary description 55, wherein
said (b) and said (c) are consecutively performed in the same treatment vessel.

### Reference Signs List

1 Group III nitride stack (stack)
10 SiC substrate
20 Stack structure
30 Nucleation layer
40 Channel layer
50 Barrier layer
60 Cap layer

What is claimed is:

1. A group III nitride stack comprising
a SiC substrate, and
a stack structure provided on the SiC substrate and formed by epitaxially growing a group III nitride crystal, wherein
the stack structure has an average density of surface defects of 10.0 defects/cm² or less in an internal region of a surface of the stack structure, the surface defects each having a size of 0.165 μm or more and 2.0 μm or less, the internal region being a region excluding a width of 5 mm from an outer edge of the surface of the stack structure, and
when the internal region is segmented into a plurality of 10 mm-square region segments and a density of the surface defects in each region segment is measured, the maximum value of the density is 50.0 defects/cm² or less.

2. The group III nitride stack according to claim 1, wherein
the average density is 7.0 defects/cm² or less, and
the maximum value of the density is 30.0 defects/cm² or less.

3. The group III nitride stack according to claim 1, wherein
the average density is 5.0 defects/cm² or less, and
the maximum value of the density is 20.0 defects/cm² or less.

4. The group III nitride stack according to claim 1, wherein
the stack structure comprises
a nucleation layer provided on the SiC substrate and containing aluminum nitride, and
a channel layer provided on the nucleation layer and expressed by a composition formula of InₓAl_{y}Ga_{(1-x-y)}N (0≤x≤1, 0≤y≤1, x+y≤1),
the surface of the stack structure being the channel layer.

5. The group III nitride stack according to claim 1, wherein
the stack structure comprises
a nucleation layer provided on the SiC substrate and containing aluminum nitride,
a channel layer provided on the nucleation layer and containing a group III nitride expressed by a composition formula of InₓAl_{y}Ga_{(1-x-y)}N (0≤x≤1, 0≤y≤1, x+y≤1), and
a functional layer provided on the channel layer and containing a group III nitride expressed by a composition formula of InₓAl_{y}Ga_{(1-x-y)}N (0≤x≤1, 0≤y≤1, x+y≤1),
the surface of the stack structure being the functional layer.

6. The group III nitride stack according to claim 1,
the stack having a diameter of 4 inches or more.

7. A group III nitride stack comprising
a SiC substrate, and
a stack structure provided on the SiC substrate and formed by epitaxially growing a group III nitride crystal, wherein
the stack structure has relative yellow intensities of 1.30 or less, each of the relative yellow intensities being a ratio of yellow emission intensity to band edge emission intensity of photoluminescence at a surface center of the stack structure, and
a fluctuation rate (Xₘₐₓ−Xₘᵢₙ)/X_{avg} of the relative yellow intensities is 20% or less, wherein in the fluctuation rate, Xₘₐₓ, Xₘᵢₙ, and X_{avg} respectively denote the maximum value, minimum value, and average of the relative yellow intensities taken at three or more points in an internal region of the surface of the stack structure, the internal region excluding a width of 5 mm from the outer edge of the surface, the three or more points being freely selected along a central line of the surface, the three or more points including the center of the surface and two or more points spaced apart from the center.

8. The group III nitride stack according to claim 7, wherein
the relative yellow intensity at the surface center is 1.25 or less, and
the fluctuation rate of the relative yellow intensities is 15% or less.

9. The group III nitride stack according to claim 7, wherein
the relative yellow intensity at the surface center is 1.20 or less, and
the fluctuation rate of the relative yellow intensities is 10% or less.

10. The group III nitride stack according to claim 7, wherein
the stack structure comprises
a nucleation layer provided on the SiC substrate, and
a channel layer provided on the nucleation layer and expressed by a composition formula of InₓAl_{y}GaN (0≤x≤1, 0≤y≤1, x+y≤1),
the surface of the stack structure being the channel layer.

11. The group III nitride stack according to claim 7, wherein
the stack structure comprises
a nucleation layer provided on the SiC substrate,
a channel layer provided on the nucleation layer and expressed by a composition formula of InₓAl_{y}GaN (0≤x≤1, 0≤y≤1, x+y≤1), and
a functional layer provided on the channel layer and containing a group III nitride having a wider band gap than gallium nitride,
the surface of the stack structure being the functional layer.

12. The group III nitride stack according to claim 7,
the stack having a diameter of 4 inches or more.

13. A method of manufacturing a group III nitride stack, the method comprising
(a) preparing a SiC substrate,
(b) supplying a halogen-containing gas onto the SiC substrate to desorb Si from a principal surface of the SiC substrate and form a Si-deficient region in a surface layer of the principal surface,
(c) supplying a hydrogen-containing gas onto the SiC substrate having the Si-deficient region to remove the Si-deficient region, and performing surface treatment of the principal surface, and
(d) growing a group III nitride crystal on the principal surface having undergone the treatment.

14. The method of manufacturing a group III nitride stack according to claim 13, wherein
said (c) is performed under a condition under which the Si-deficient region is removed from the entire area of the principal surface of the SiC substrate.

15. The method of manufacturing a group III nitride stack according to claim 13, wherein
said (b) is performed under a condition under which the Si-deficient region is formed over the entire area of the principal surface of the SiC substrate.
